(19) United States
(12) Patent Application Publication
(10) Pub. No.: US 2010/0167024 A1
(43) Pub. Date: Jul. 1, 2010

(54) NEGATIVE-TONE RADIATION-SENSITIVE COMPOSITION, CURED PATTERN FORMING METHOD, AND CURED PATTERN

(75) Inventors: Norihiro Natsume, Tokyo (JP); Takanori Kishida, Tokyo (JP); Hayato Namai, Tokyo (JP); Kyoyu Yasuda, Tokyo (JP); Satoshi Dei, Tokyo (JP); Koichi Hasegawa, Tokyo (JP)

Correspondence Address: Ditthavong Mori & Steiner, P.C., 918 Prince Street, Alexandria, VA, 22314, US

(73) Assignee: JSR Corporation, Tokyo (JP)

(21) Appl. No.: 12/647,375

(22) Filed: Dec. 24, 2009

(30) Foreign Application Priority Data
Dec. 25, 2008 (JP) 2008-330635
Apr. 22, 2009 (JP) 2009-104536

(51) Int. Cl. B32B 3/10; G03F 7/004; G03F 7/20

(52) U.S. Cl. 428/195.1; 430/270.1; 430/286.1; 430/287.1; 430/325

(57) ABSTRACT

A negative-tone radiation-sensitive composition includes a polymer, a photoacid generator, and a solvent. The polymer has a polystyrene-reduced weight average molecular weight of 4000 to 200,000, and is obtained by hydrolysis and condensation of at least one hydrolyzable silane compound among compounds shown by RₐSi(OR¹)₄₋ₐ, Si(OR²)₄ and R³ₓ(R⁴O)₃₋ₓSi—(R⁷)_{z}—Si(OR⁵)_{3-y}R⁶_{y}. “R” represents a fluorine atom, an alkylcarbonyloxy group, or a linear or branched alkyl group having 1 to 5 carbon atoms. “R¹” represents a monovalent organic group. “R²” represents a monovalent organic group. “R3” and “R6” individually represent a fluorine atom, an alkylcarbonyloxy group, or a linear or branched alkyl group having 1 to 5 carbon atoms “R⁴” and “R⁵” individually represent a monovalent organic group. “R⁷” represents an oxygen atom, a phenylene group, or a group —(CH₂)ₘ—. The content of units derived from the compound RₐSi(OR¹)₄₋ₐ is 50 to 100 mol % of the total units forming the polymer.

### CROSS-REFERENCE TO RELATED APPLICATIONS

The present application claims priority under 35 U.S.C. §119 to Japanese Patent Applications No. 2008-330635, filed Dec. 25, 2008, and No. 2009-104536, filed Apr. 22, 2009. The contents of these applications are incorporated herein by reference in their entirety.

### BACKGROUND OF THE INVENTION

1. Field of the Invention

The present invention relates to a negative-tone radiation-sensitive composition, a cured pattern forming method, and a cured pattern.

2. Description of Related Art

A silica (SiO₂) film formed by a vacuum process such as chemical vapor deposition (CVD) has been widely used as an interlayer dielectric for semiconductor devices and the like.

In recent years, a coating-type insulating film called a spin-on-glass (SOG) film, which contains a tetraalkoxysilane hydrolyzate as the major component, has been used in order to form an interlayer dielectric with a more uniform thickness (see JP-A-5-36684, for example). Along with an increase in the degree of integration of semiconductor devices, an interlayer dielectric having a low relative dielectric constant, called an organic SOG film, which contains a polyorganosiloxane as the major component, has also been developed (see JP-A-2003-3120 and JP-A-2005-213492, for example).

However, demand for further integration and layer multiplication of semiconductor devices requires more excellent electric insulation between conductors. Therefore, development of an interlayer dielectric having a lower relative dielectric constant is desired.

An interlayer dielectric is usually processed by repetition of a pattern transfer treatment. In general, a number of different mask material layers are formed on an interlayer dielectric layer and a radiation-sensitive resin composition is applied to the top of the layers. After forming a desired circuit pattern on the radiation-sensitive resin composition by reduced projection exposure and development, the pattern is transferred onto the sequentially laminated mask material layers.

After the pattern has been transferred from the mask material layer onto the interlayer dielectric layer, the mask material layer is removed to complete the processing of the interlayer dielectric. Since the method generally employed for processing an interlayer dielectric requires enormous time and effort and is unduly inefficient in this way, an improvement has been desired.

### SUMMARY OF THE INVENTION

According to one aspect of the present invention, a negative-tone radiation-sensitive composition includes (A) a polymer, (B) a photoacid generator, and (C) a solvent. The polymer (A) is obtained by hydrolysis and condensation of at least one hydrolyzable silane compound selected from (1) a hydrolyzable silane compound shown by the following formula (1), (2) a hydrolyzable silane compound shown by the following formula (2), and (3) a hydrolyzable silane compound shown by the following formula (3).

RₐSi(OR¹)₄₋ₐ (1)

wherein R represents a fluorine atom, a linear or branched alkyl group having 1 to 5 carbon atoms, an alkenyl group having 2 to 6 carbon atoms, or an alkylcarbonyloxy group, R¹ represents a monovalent organic group, and a represents an integer from 1 to 3.

Si(OR²)₄ (2)

wherein R² represents a monovalent organic group.

R³ₓ(R⁴O)₃₋ₓSi—(R⁷)_{z}—Si(OR⁵)_{3-y}R⁶_{y} (3)

wherein R³ and R⁶ individually represent a fluorine atom, an alkylcarbonyloxy group, or a linear or branched alkyl group having 1 to 5 carbon atoms, R⁴ and R⁵ individually represent a monovalent organic group, x and y individually represent a number from 0 to 2, and R⁷ represents a phenylene group or a group —(CH₂)ₘ— (wherein m represents an integer from 1 to 6), and z represents 0 or 1.

The content of units derived from the compound (1) is 50 to 100 mol % of the total units forming the polymer (A).

According to another aspect of the present invention, a method for forming a cured pattern includes (I-1) applying the above described negative-tone radiation-sensitive composition to a substrate to form a film, (I-2) baking the resulting film, (I-3) exposing the baked film, (I-4) developing the exposed film using a developer to form a negative-tone pattern, and (I-5) applying at least one of high energy rays and heat to the resulting negative-tone pattern to form a cured pattern.

According to the other aspect of the present invention, a method for forming a cured pattern includes (II-1) applying the above described negative-tone radiation-sensitive to a substrate, followed by exposure and development to form a negative-tone hole pattern substrate having a negative-tone hole pattern, (II-2) applying the negative-tone radiation-sensitive composition to the resulting negative-tone hole pattern substrate, followed by exposure and development to form a negative-tone trench pattern on the negative-tone hole pattern substrate, thereby forming a negative-tone dual damascene pattern substrate, and (II-3) applying at least one of high energy rays and heat to the resulting negative-tone dual damascene pattern substrate to form a cured pattern having a dual damascene structure.

According to further aspect of the present invention, a cured pattern is obtained by either one of the above described methods.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings.

FIGS. 1A-1F are diagrams schematically showing a cross-sectional configuration of a pattern.

FIGS. 2A-2D are diagrams schematically showing a method of forming a cured pattern having a dual damascene structure.

FIG. 3 shows a photograph of a cross-sectional configuration of a negative-tone pattern having a dual damascene structure obtained in Examples 3-4.

### DESCRIPTION OF EXEMPLARY EMBODIMENTS

The negative-tone radiation-sensitive composition according to an embodiment of the present invention includes (A) a polymer (hereinafter referred to from time to time as “polymer (A)”), (B) a photoacid generator (hereinafter referred to from time to time as “acid generator (B)”), and (C) a solvent (hereinafter referred to from time to time as “solvent (C)”).

### [1] Polymer (A)

The polymer (A) is obtained by hydrolysis and condensation of at least one hydrolyzable silane compound selected from a hydrolyzable silane compound shown by the following formula (1) (hereinafter referred to from time to time as “compound (1)”), a hydrolyzable silane compound shown by the following formula (2) (hereinafter referred to from time to time as “compound (2)”), and a hydrolyzable silane compound shown by the following formula (3) (hereinafter referred to from time to time as “compound (3)”).

RₐSi(OR¹)₄₋ₐ (1)

wherein R represents a fluorine atom, a linear or branched alkyl group having 1 to 5 carbon atoms, an alkenyl group having 2 to 6 carbon atoms, or an alkylcarbonyloxy group, R¹ represents a monovalent organic group, and a represents an integer from 1 to 3,

Si(OR²)₄ (2)

wherein R² represents a monovalent organic group.

R3x(R4O)3-xSi—(R7)z-Si(OR5)3-yR6y (3)

wherein R³ and R⁶ individually represent a fluorine atom, an alkylcarbonyloxy group, or a linear or branched alkyl group having 1 to 5 carbon atoms, R⁴ and R⁵ individually represent a monovalent organic group, x and y individually represent a number from 0 to 2, and R⁷ represents an oxygen atom, a phenylene group, or a group —(CH₂)ₘ— (wherein m represents an integer from 1 to 6), and z represents 0 or 1.

### [1-1] Compound (1)

As examples of the linear or branched alkyl group having 1 to 5 carbon atoms represented by R in the formula (1), a methyl group, an ethyl group, a propyl group, a butyl group, a vinyl group, a propenyl group, a 3-butenyl group, a 3-pentenyl group, and a 3-hexenyl group can be given. One or more hydrogen atoms in these alkyl groups may be substituted with a fluorine atom or the like.

As examples of the alkenyl group having 2 to 6 carbon atoms represented by R, a vinyl group, a propenyl group, a 3-butenyl group, a 3-pentenyl group, a 3-hexenyl group, and the like can be given.

As examples of the alkylcarbonyloxy group represented by R, a methylcarbonyloxy group, an ethylcarbonyloxy group, a propylcarbonyloxy group, a butylcarbonyloxy group, a vinylcarbonyloxy group, and an allylcarbonyloxy group can be given.

When there are two or more R groups (i.e. when a is 2 or 3), either all R groups may be the same or all or some R groups may be different from the other R groups.

As examples of the monovalent organic group represented by R¹, an alkyl group, an alkenyl group, an aryl group, an allyl group, and a glycidyl group can be given. Among these, an alkyl group and an aryl group are preferable.

As examples of the alkyl group, a linear or branched alkyl group having 1 to 5 carbon atoms can be given. Specific examples include a methyl group, an ethyl group, a propyl group, and a butyl group. One or more hydrogen atoms in these alkyl groups may be substituted with a fluorine atom or the like. As examples of the aryl group, a phenyl group, a naphthyl group, a methylphenyl group, an ethylphenyl group, a chlorophenyl group, a bromophenyl group, and a fluorophenyl group can be given. Of these, a phenyl group is preferable.

Examples of the alkenyl group include a vinyl group, a propenyl group, a 3-butenyl group, a 3-pentenyl group, and a 3-hexenyl group.

The alkenyl group having 2 to 6 carbon atoms represented by R in the formula (1) is preferably a group shown by the following formula (i),

CH₂═CH—(CH₂)ₙ—* (i)

wherein n is an integer from 0 to 4 and * indicates a bonding hand.

n in the formula (i) is an integer from 0 to 4, preferably 0 or 1, and more preferably 0 (vinyl group).

As examples of the alkenyl group other than those represented by the formula (i), a butenyl group, a pentenyl group, and a hexenyl group which are shown other than the formula (i) can be given.

As specific examples of the compound (1) shown by the formula (1), methyltrimethoxysilane, methyltriethoxysilane, methyltri-n-propoxysilane, methyltriisopropoxysilane, methyltri-n-butoxysilane, methyltri-sec-butoxysilane, methyltri-t-butoxysilane, methyltriphenoxysilane, ethyltrimethoxysilane, ethyltriethoxysilane, ethyltri-n-propoxysilane, ethyltriisopropoxysilane, ethyltri-n-butoxysilane, ethyltri-sec-butoxysilane, ethyltri-t-butoxysilane, ethyltriphenoxysilane, n-propyltrimethoxysilane, n-propyltriethoxysilane, n-propyltri-n-propoxysilane, n-propyltriisopropoxysilane, n-propyltri-n-butoxysilane, n-propyltri-sec-butoxysilane, n-propyltri-t-butoxysilane, n-propyltriphenoxysilane, isopropyltrimethoxysilane, isopropyltriethoxysilane, isopropyltri-n-propoxysilane, isopropyltriisopropoxysilane, isopropyltri-n-butoxysilane, isopropyltri-sec-butoxysilane, isopropyltri-t-butoxysilane, isopropyltriphenoxysilane, n-butyltrimethoxysilane, n-butyltriethoxysilane, n-butyltri-n-propoxysilane, n-butyltriisopropoxysilane, n-butyltri-n-butoxysilane, n-butyltri-sec-butoxysilane, n-butyltri-t-butoxysilane, n-butyltriphenoxysilane, sec-butyltrimethoxysilane, sec-butyliso-triethoxysilane, sec-butyltri-n-propoxysilane, sec-butyltriisopropoxysilane, sec-butyltri-n-butoxysilane, sec-butyltri-sec-butoxysilane, sec-butyltri-t-butoxysilane, sec-butyltriphenoxysilane, tert-butyltrimethoxysilane, tert-butyltriethoxysilane, tert-butyltri-n-propoxysilane, tert-butyltriisopropoxysilane, tert-butyltri-n-butoxysilane, tert-butyltri-sec-butoxysilane, tert-butyltri-t-butoxysilane, tert-butyltriphenoxysilane, dimethyldimethoxysilane, dimethyldiethoxy silane, dimethyl-di-n-propoxysilane, dimethyldiisopropoxysilane, dimethyl-di-n-butoxysilane, dimethyl-di-sec-butoxysilane, dimethyl-di-tert-butoxysilane, dimethyldiphenoxysilane,

diethyldimethoxysilane, diethyldiethoxysilane, diethyl-di-n-propoxysilane, diethyldiisopropoxysilane, diethyl-di-n-butoxysilane, diethyldi-sec-butoxysilane, diethyl-di-tert-butoxysilane, diethyldiphenoxysilane, di-n-propyldimethoxysilane, di-n-propyldiethoxysilane, di-n-propyl-di-n-propoxysilane, di-n-propyldiisopropoxysilane, di-n-propyl-di-n-butoxysilane, di-n-propyl-di-sec-butoxysilane, di-n-propyl-di-tert-butoxysilane, di-n-propyl-di-phenoxysilane,
diisopropyldimethoxysilane, diisopropyldiethoxysilane, diisopropyl-di-n-propoxysilane, diisopropyldiisopropoxysilane, diisopropyl-di-n-butoxysilane, diisopropyl-di-sec-butoxysilane, diisopropyl-di-tert-butoxysilane, diisopropyldiphenoxysilane, di-n-butyldimethoxysilane, di-n-butyldiethoxysilane, di-n-butyl-di-n-propoxysilane, di-n-butyldiisopropoxysilane, di-n-butyl-di-n-butoxysilane, di-n-butyl-di-sec-butoxysilane, di-n-butyl-di-tert-butoxysilane, di-n-butyl-di-phenoxysilane, di-sec-butyldimethoxysilane, di-sec-butyldiethoxysilane, di-sec-butyl-di-n-propoxysilane, di-sec-butyldiisopropoxysilane, di-sec-butyl-di-n-butoxysilane, di-sec-butyl-di-sec-butoxysilane, di-sec-butyl-di-tert-butoxysilane, di-sec-butyl-di-phenoxysilane, di-tert-butyldimethoxysilane, di-tert-butyldiethoxysilane, di-tert-butyldi-n-propoxysilane, di-tert-butyldiisopropoxysilane, di-tert-butyldi-n-butoxysilane, di-tert-butyldi-sec-butoxysilane, di-tert-butyl-di-tert-butoxysilane, di-tert-butyldi-phenoxysilane, vinyltrimethoxysilane, vinyltriethoxysilane, vinyltri-n-propoxysilane, vinyltri-iso-propoxysilane, vinyltri-n-butoxysilane, vinyltri-sec-butoxysilane, vinyltri-tert-butoxysilane, vinyltriphenoxysilane, allyltrimethoxysilane, allyltriethoxysilane, allyltri-n-propoxysilane, allyltri-iso-propoxysilane, allyltri-n-butoxysilane, allyltri-sec-butoxysilane, allyltri-tert-butoxysilane, and allyltriphenoxysilane can be given.

Among these compounds (1), methyltrimethoxysilane, methyltriethoxysilane, methyltri-n-propoxysilane, methyltri-iso-propoxysilane, ethyltrimethoxysilane, ethyltriethoxysilane, dimethyldimethoxysilane, dimethyldiethoxysilane, diethyldimethoxysilane, diethyldiethoxysilane, and the like in which R is an alkyl group, particularly a methyl group, are preferable in order to obtain a low-dielectric-constant cured pattern.

Moreover, a compound in which R is an alkenyl group having 2 to 6 carbon atoms, particularly a group shown by the above-formula (i), is preferable due to comparatively small film shrinkage (pattern shrinkage) after curing and the capability of producing a cured film with high modulus of elasticity. Particularly preferable specific examples of such a compound include vinyltrimethoxysilane, vinyltriethoxysilane, allyltrimethoxysilane, and allyltriethoxysilane.

These compounds (1) may be used either individually, or in a combination of two or more.

### [1-2] Compound (2)

The description of the monovalent organic group for R¹ in the formula (1) applies as is to the monovalent organic group for R² in the formula (2).

Specific examples of the compound (2) shown by of the formula (2) include tetramethoxysilane, tetraethoxysilane, tetra-n-propoxysilane, tetra-iso-propoxysilane, tetra-n-butoxysilane, tetra-sec-butoxysilane, tetra-tert-butoxysilane, and tetraphenoxysilane.

Among these compounds, tetramethoxysilane and tetraethoxysilane are preferable due to capability of widening the depth of focus (DOF) of the negative-tone radiation-sensitive composition.

These compounds (2) may be used either individually, or in a combination of two or more.

### [1-3] Other Compounds (3)

As description for the fluorine atom, alkylcarbonyloxy group, and linear or branched alkyl group having 1 to 5 carbon atoms for R³ and R⁶ in the formula (3), the descriptions of these groups for R in the formula (1) apply as is. The description of the monovalent organic group for R¹ in the formula (1) applies as is to the monovalent organic group for R4 and R5.

As examples of the compound in which z is zero in the general formula (3), hexamethoxydisilane, hexaethoxydisilane, hexaphenoxydisilane, 1,1,1,2,2-pentamethoxy-2-methyldisilane, 1,1,1,2,2-pentaethoxy-2-methyldisilane, 1,1,1,2,2-pentaphenoxy-2-methyldisilane, 1,1,1,2,2-pentamethoxy-2-ethyldisilane, 1,1,1,2,2-pentaethoxy-2-ethyldisilane, 1,1,1,2,2-pentaphenoxy-2-ethyldisilane, 1,1,1,2,2-pentamethoxy-2-phenyldisilane, 1,1,1,2,2-pentaethoxy-2-phenyldisilane, 1,1,1,2,2-pentaphenoxy-2-phenyldisilane, 1,1,2,2-tetramethoxy-1,2-dimethyldisilane, 1,1,2,2-tetraethoxy-1,2-dimethyldisilane, 1,1,2,2-tetraphenoxy-1,2-dimethyldisilane, 1,1,2,2-tetramethoxy-1,2-diethyldisilane, 1,1,2,2-tetraethoxy-1,2-diethyldisilane, 1,1,2,2-tetraphenoxy-1,2-diethyldisilane, 1,1,2,2-tetramethoxy-1,2-diphenyldisilane, 1,1,2,2-tetraethoxy-1,2-diphenyldisilane, 1,1,2,2-tetraphenoxy-1,2-diphenyldisilane, 1,1,2-trimethoxy-1,2,2-trimethyldisilane, 1,1,2-triethoxy-1,2,2-trimethyldisilane, 1,1,2-triphenoxy-1,2,2-trimethyldisilane, 1,1,2-trimethoxy-1,2,2-triethyldisilane, 1,1,2-triethoxy-1,2,2-triethyldisilane, 1,1,2-triphenoxy-1,2,2-triethyldisilane, 1,1,2-trimethoxy-1,2,2-triphenyldisilane, 1,1,2-triethoxy-1,2,2-triphenyldisilane, 1,1,2-triphenoxy-1,2,2-triphenyldisilane, 1,2-dimethoxy-1,1,2,2-tetramethyldisilane, 1,2-diethoxy-1,1,2,2-tetramethyldisilane, 1,2-diphenoxy-1,1,2,2-tetramethyldisilane, 1,2-dimethoxy-1,1,2,2-tetraethyldisilane, 1,2-diethoxy-1,1,2,2-tetraethyldisilane, 1,2-diphenoxy-1,1,2,2-tetraethyldisilane, 1,2-dimethoxy-1,1,2,2-tetraphenyldisilane, 1,2-diethoxy-1,1,2,2-tetraphenyldisilane, and 1,2-diphenoxy-1,1,2,2-tetraphenyldisilane can be given.

Among these compounds, hexamethoxydisilane, hexaethoxydisilane, 1,1,2,2-tetramethoxy-1,2-dimethyldisilane, 1,1,2,2-tetraethoxy-1,2-dimethyldisilane, 1,1,2,2-tetramethoxy-1,2-diphenyldisilane, 1,2-dimethoxy-1,1,2,2-tetramethyldisilane, 1,2-diethoxy-1,1,2,2-tetramethyldisilane, 1,2-dimethoxy-1,1,2,2-tetraphenyldisilane, 1,2-diethoxy-1,1,2,2-tetraphenyldisilane, and the like are preferable.

As examples of the compound (3) of the general formula (3) in which z is 1, bis(trimethoxysilyl)methane, bis(triethoxysilyl)methane, bis(tri-n-propoxysilyl)methane, bis(tri-iso-propoxysilyl)methane, bis(tri-n-butoxysilyl)methane, bis(tri-sec-butoxysilyl)methane, bis(tri-tert-butoxysilyl)methane, 1,2-bis(trimethoxysilyl)ethane, 1,2-bis(triethoxysilyl)ethane, 1,2-bis(tri-n-propoxysilyl)ethane, 1,2-bis(tri-iso-propoxysilyl)ethane, 1,2-bis(tri-n-butoxysilyl)ethane, 1,2-bis(tri-sec-butoxysilyl)ethane, 1,2-bis(tri-tert-butoxysilyl)ethane, 1-(dimethoxymethylsilyl)-1-(trimethoxysilyl)methane, 1-(diethoxymethylsilyl)-1-(triethoxysilyl)methane, 1-(di-n-propoxymethylsilyl)-1-(tri-n-propoxysilyl)methane, 1-(di-iso-propoxymethylsilyl)-1-(tri-iso-propoxysilyl)methane, 1-(di-n-butoxymethylsilyl)-1-(tri-n-butoxysilyl)methane, 1-(di-sec-butoxymethylsilyl)-1-(tri-sec-butoxysilyl)methane, 1-(di-tert-butoxymethylsilyl)-1-(tri-tert-butoxysilyl)methane, 1-(dimethoxymethylsilyl)-2-(trimethoxysilyl)ethane, 1-(diethoxymethylsilyl)-2-(triethoxysilyl)ethane, 1-(di-n-propoxymethylsilyl)-2-(tri-n-propoxysilyl)ethane, 1-(di-iso-propoxymethylsilyl)-2-(tri-iso-propoxysilyl)ethane, 1-(di-n-butoxymethylsilyl)-2-(tri-n-butoxysilyl)ethane, 1-(di-sec-butoxymethylsilyl)-2-(tri-sec-butoxysilyl)ethane, 1-(di-tert-butoxymethylsilyl)-2-(tri-tert-butoxysilyl)ethane, bis(dimethoxymethylsilyl)methane, bis(diethoxymethylsilyl)methane, bis(di-n-propoxymethylsilyl)methane, bis(di-iso-propoxymethylsilyl)methane, bis(di-n-butoxymethylsilyl)methane, bis(di-sec-butoxymethylsilyl)methane, bis(di-tert-butoxymethylsilyl)methane, 1,2-bis(dimethoxymethylsilyl)ethane, 1,2-bis(diethoxymethylsilyl)ethane, 1,2-bis(di-n-propoxymethylsilyl)ethane, 1,2-bis(di-iso-propoxymethylsilyl)ethane, 1,2-bis(di-n-butoxymethylsilyl)ethane, 1,2-bis(di-sec-butoxymethylsilyl)ethane, 1,2-bis(di-tert-butoxymethylsilyl)ethane, 1,2-bis(trimethoxysilyl)benzene, 1,2-bis(triethoxysilyl)benzene, 1,2-bis(tri-n-propoxysilyl)benzene, 1,2-bis(tri-iso-propoxysilyl)benzene, 1,2-bis(tri-n-butoxysilyl)benzene, 1,2-bis(tri-sec-butoxysilyl)benzene, 1,2-bis(tri-tert-butoxysilyl)benzene, 1,3-bis(trimethoxysilyl)benzene, 1,3-bis(triethoxysilyl)benzene, 1,3-bis(tri-n-propoxysilyl)benzene, 1,3-bis(tri-iso-propoxysilyl)benzene, 1,3-bis(tri-n-butoxysilyl)benzene, 1,3-bis(tri-sec-butoxysilyl)benzene, 1,3-bis(tri-tert-butoxysilyl)benzene, 1,4-bis(trimethoxysilyl)benzene, 1,4-bis(triethoxysilyl)benzene, 1,4-bis(tri-n-propoxysilyl)benzene, 1,4-bis(tri-iso-propoxysilyl)benzene, 1,4-bis(tri-n-butoxysilyl)benzene, 1,4-bis(tri-sec-butoxysilyl)benzene, and 1,4-bis(tri-tert-butoxysilyl)benzene can be given.

Of these, bis(trimethoxysilyl)methane, bis(triethoxysilyl)methane, 1,2-bis(trimethoxysilyl)ethane, 1,2-bis(triethoxysilyl)ethane, 1-(dimethoxymethylsilyl)-1-(trimethoxysilyl)methane, 1-(diethoxymethylsilyl)-1-(triethoxysilyl)methane, 1-(dimethoxymethylsilyl)-2-(trimethoxysilyl)ethane, 1-(diethoxymethylsilyl)-2-(triethoxysilyl)ethane, bis(dimethoxymethylsilyl)methane, bis(diethoxymethylsilyl)methane, 1,2-bis(dimethoxymethylsilyl)ethane, 1,2-bis(diethoxymethylsilyl)ethane, 1,2-bis(trimethoxysilyl)benzene, 1,2-bis(triethoxysilyl)benzene, 1,3-bis(trimethoxysilyl)benzene, 1,3-bis(triethoxysilyl)benzene, 1,4-bis(trimethoxysilyl)benzene, 1,4-bis(triethoxysilyl)benzene, and the like are preferable.

These compounds shown by the formula (3) may be used either individually, or in a combination of two or more.

The polymer (A) may include units derived from a compound other than the compounds (1) to (3).

[1-4] Content of Units Derived from Hydrolyzable Silane Compound

The content of units derived from the compound (1) in the polymer (A) is 80 to 100 mol %, and preferably 85 to 95 mol % of the total units contained in the polymer (A).

When this content is 80 to 100 mol %, excellent balance between the process margin (depth of focus, etc.) during curing treatment and cured film properties (low dielectric constant, etc.) can be ensured. In addition, in order to ensure excellent balance between the process margin (depth of focus, etc.) during curing treatment and cured film properties (low dielectric constant, etc.), it is preferable that all units contained in the polymer (A) consist only of units derived from the compound (1) and units derived from the compound (2).

The content of the units derived from a compound having an alkenyl group among the above compound (1) is preferably 1 to 60 mol %, more preferably 5 to 50 mol %, and still more preferably 10 to 40 mol % for 100 mol % of all units included in the polysiloxane (A). The content from 1 to 60 mol % is preferable due to comparatively small film shrinkage (pattern shrinkage) after curing and the capability of producing a cured film with high modulus of elasticity.

### [1-5] Molecular Weight of Polymer (A)

The polystyrene-reduced weight average molecular weight (Mw) of the polymer (A) determined by gel permeation chromatography is preferably 1000 to 200,000, and more preferably 2000 to 150,000. When the Mw is more than 200,000, the polymer is easily gelled. On the other hand, when the Mw is less than 1000, problems may occur in applicability and storage stability. When the above compound (1) includes a compound having a methyl group for R in the formula (1), Mw is preferably 4000 to 200,000, and more preferably 7000 to 20,000. When the Mw of the polymer (A) is 4000 to 200,000, excellent balance between the process margin (marginal resolution, depth of focus, and exposure margin) during curing treatment and cured film properties (low dielectric constant, etc.) can be ensured. If the Mw is 7000 to 20,000, a rectangular pattern shape can be obtained. In addition, if the Mw is 4000 to 12,000, the composition is particularly-suitable for forming line-and-space patterns.

### [1-6] Carbon Atom Content

The carbon atom content of the polymer (A) is preferably 8 to 40 atom %, and more preferably 8 to 20 atom %. If the carbon atom content is less than 8 atom %, it is difficult to obtain a silica-based film with a sufficiently low relative dielectric constant using a radiation-sensitive resin composition containing the polymer (A). On the other hand, if the carbon atom content is more than 40 atom %, film shrinkage (pattern shrinkage) occurs to as large extent after curing so that it is difficult to obtain a desired pattern.

The carbon atom content (atom %) of the polymer (A) can be determined from the elemental analysis of a reaction product obtained by hydrolysis of a hydrolyzable silane compound used for synthesizing the polymer (A), in which the hydrolyzable groups are completely hydrolyzed into silanol groups, followed by complete condensation of the silanol groups into siloxane bonds. Specifically, the following formula is used.

Carbon atom content(atom %)=(carbon atom number of organic silica sol)/(total atom number of organic silica sol)×100

### [1-8] Preparation of Polymer (A)

The polymer (A) is usually prepared by dissolving hydrolyzable silane compounds (compounds (1) to (3)) as starting raw materials in an organic solvent, and intermittently or continuously adding water to the solution or adding the solution to water to effect a hydrolysis/condensation reaction. In this instance, a catalyst may be previously dispersed in the organic solvent or may be dissolved or dispersed in water which is added later. The temperature of the hydrolysis/condensation reaction is usually 0 to 100° C.

Although there are no particular limitations to water used for the hydrolysis/condensation reaction, ion-exchanged water is preferably used. Water is used in an amount of 0.25 to 3 mol, and preferably 0.3 to 2.5 mol, per one mol of the alkoxy groups in the hydrolys able silane compounds used in the reaction.

There are no particular limitations to the organic solvent insofar as an organic solvent used in this type of reaction is selected. As examples, propylene glycol monoethyl ether, propylene glycol monomethyl ether, propylene glycol monopropyl ether, and the like can be given.

As examples of the catalyst, a metal chelate compound, an organic acid, an inorganic acid, an organic base, and an inorganic base can be given.

As examples of the metal chelate compound, a titanium chelate compound, a zirconium chelate compound, and an aluminum chelate compound can be given. Specifically, compounds described in JP-A-2000-356854 and the like can be used.

As examples of the organic acids, acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, shikimic acid, 2-ethylhexanoic acid, oleic acid, stearic acid, linolic acid, linoleic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartaric acid can be given.

As examples of the inorganic acid, hydrochloric acid, nitric acid, sulfuric acid, hydrofluoric acid, phosphoric acid, and the like can be given.

As examples of the organic salts, pyridine, pyrrole, piperazine, pyrrolidine, piperidine, picoline, trimethylamine, triethylamine, monoethanolamine, diethanolamine, dimethyl monoethanolamine, monomethyl diethanolamine, triethanolamine, diazabicyclooctane, diazabicyclononane, diazabicycloundecene, and tetramethylammonium hydroxide can be given.

As examples of the inorganic base, ammonia, sodium hydroxide, potassium hydroxide, barium hydroxide, calcium hydroxide, and the like can be given.

Of these catalysts, metal chelate compounds, organic acids, and inorganic acids are preferable. These catalysts may be used either individually, or in a combination of two or more.

The catalysts are usually used in the amount of 0.01 to 10 parts by mass, preferably 0.01 to 10 parts by mass, based on 100 parts by mass of the hydrolyzable silane compound.

After the hydrolysis/condensation reaction, it is preferable to remove reaction by-products such as a lower alcohol (e.g. methanol and ethanol).

Any method which does not cause the reaction of the hydrolyzate and/or condensate of the silane compound to proceed can be used for removing the reaction by-products without a particular limitation. For example, the reaction by-products can be removed by evaporation under reduced pressure when the boiling point of the reaction by-products is lower than the boiling point of the organic solvent.

### [2] Acid Generator (B)

The acid generator (B) generates an acid upon exposure. The acid generated causes the resin component to crosslink As a result, exposed areas of the resist film become scarcely soluble in an alkaline developer, whereby a negative-tone resist pattern is formed.

As examples of the acid generator (B), onium salt compounds such as a sulfonium salt and an iodonium salt, organohalide compounds, sulfone compounds such as disulfones and diazomethanesulfones, and the like can be given.

As specific examples of the acid generator (B), triphenylsulfonium salt compounds such as triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, triphenylsulfonium 2-(3-tetracyclo[4.4.0.1^{2,5}. 1^{7,10}]dodecanyl)-1,1-difluoroethanesulfonate, triphenylsulfonium N,N′-bis(nonafluoro-n-butanesulfonyl)imidate, and triphenylsulfonium camphorsulfonate; 4-cyclohexylphenyldiphenylsulfonium salt compounds such as 4-cyclohexylphenyldiphenylsulfonium trifluoromethanesulfonate, 4-cyclohexylphenyldiphenylsulfonium nonafluoro-n-butanesulfonate, 4-cyclohexylphenyldiphenylsulfonium perfluoro-n-octanesulfonate, 4-cyclohexylphenyldiphenylsulfonium 2-bicyclo[2.2.1]hept-2-yl-1,1,2,2-tetrafluoroethanesulfonate, 4-cyclohexylphenyldiphenylsulfonium 2-(3-tetracyclo[4.4.0.1^{2,5}.1^{7,10}]dodecanyl)-1,1-difluoroethanesulfonate, 4-cyclohexylphenyldiphenylsulfonium N,N′-bis(nonafluoro-n-butanesulfonyl)imidate, and 4-cyclohexylphenyldiphenylsulfonium camphorsulfonate; 4-t-butylphenyldiphenylsulfonium salt compounds such as 4-t-butylphenyldiphenylsulfonium trifluoromethanesulfonate, 4-t-butylphenyldiphenyl sulfonium nonafluoro-n-butanesulfonate, 4-t-butylphenyldiphenylsulfonium perfluoro-n-octanesulfonate, 4-t-butylphenyldiphenylsulfonium 2-bicyclo[2.2.1]hept-2-yl-1,1,2,2-tetrafluoroethanesulfonate, 4-t-butylphenyldiphenylsulfonium 2-(3-tetracyclo[4.4.0.1^{2,5}. 1^{7,10}]dodecanyl)-1,1-difluoroethanesulfonate, 4-t-butylphenyldiphenylsulfonium N,N′-bis(nonafluoro-n-butanesulfonyl)imidate, and 4-t-butylphenyldiphenylsulfonium camphorsulfonate; tri(4-t-butylphenyl)sulfonium salt compounds such as tri(4-t-butylphenyl)sulfonium trifluoromethanesulfonate, tri(4-t-butylphenyl)sulfonium nonafluoro-n-butanesulfonate, tri(4-t-butylphenyl)sulfonium perfluoro-n-octanesulfonate, tri(4-t-butylphenyl)sulfonium 2-bicyclo[2.2.1]hept-2-yl-1,1,2,2-tetrafluoroethanesulfonate, tri(4-t-butylphenyl)sulfonium 2-(3-tetracyclo[4.4.0.1^{2,5}.1^{7,10}]dodecanyl)-1,1-difluoroethanesulfonate, tri(4-t-butylphenyl)sulfonium N,N′-bis(nonafluoro-n-butanesulfonyl)imidate, and tri(4-t-butylphenyl)sulfonium camphorsulfonate; diphenyliodonium salt compounds such as diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, diphenyliodonium 2-(3-tetracyclo[4.4.0.1^{2,5}.1^{7,10}]dodecanyl)-1,1-difluoroethanesulfonate, diphenyliodonium N,N′-bis(nonafluoro-n-butanesulfonyl)imidate, and diphenyliodonium camphorsulfonate; bis(4-t-butylphenyl)iodonium salt compounds such as bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate, bis(4-t-butylphenyl)iodonium 2-(3-tetracyclo[4.4.0.1^{2,5}.1^{7,10}]dodecanyl)-1,1-difluoroethanesulfonate, bis(4-t-butylphenyl)iodonium N,N′-bis(nonafluoro-n-butanesulfonyl)imidate, and bis(4-t-butylphenyl)iodonium camphorsulfonate; 1-(4-n-butoxynaphthalen-1-yl)tetrahydrothiophenium salt compounds such as 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(4-n-butoxynaphthalen-1-yl)tetrahydrothiophenium 2-(3-tetracyclo[4.4.0.1^{2,5}. 1^{7,10}]dodecanyl)-1,1-difluoroethanesulfonate, 1-(4-n-butoxynaphthalen-1-yl)tetrahydrothiophenium N,N′-bis(nonafluoro-n-butanesulfonyl)imidate, and 1-(4-n-butoxynaphthalen-1-yl)tetrahydrothiophenium camphorsulfonate; 1-(3,5-dimethyl-4-hydroxyphenyl)tetrahydrothiophenium salt compounds such as 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate, 1-(3,5-dimethyl-4-hydroxyphenyl)tetrahydrothiophenium 2-bicyclo[2.2.1]hept-2-yl-1,1,2,2-tetrafluoroethanesulfonate, 1-(3,5-dimethyl-4-hydroxyphenyl)tetrahydrothiophenium 2-(3-tetracyclo[4.4.0.1^{2,5}.1^{7,10}]dodecanyl)-1,1-difluoroethanesulfonate, 1-(3,5-dimethyl-4-hydroxyphenyl)tetrahydrothiophenium N,N′-bis(nonafluoro-n-butanesulfonyl)imidate, and 1-(3,5-dimethyl-4-hydroxyphenyl)tetrahydrothiophenium camphorsulfonate; succinimide compounds such as N-(trifluoromethanesulfonyloxy)succinimide, N-(nonafluoro-n-butanesulfonyloxy)succinimide, N-(perfluoro-n-octanesulfonyloxy)succinimide, N-(2-bicyclo[2.2.1]hept-2-yl-1,1,2,2-tetrafluoroethanesulfonyloxy)succinimide, N-(2-(3-tetracyclo[4.4.0.1^{2,5}. 1^{7,10}]dodecanyl)-1,1-difluoroethanesulfonyloxy)-succinimide, and N-(camphorsulfonyloxy)succinimide; and bicyclo[2.2.1]hept-5-ene-2,3-dicarboxylmide compounds such as N-(trifluoromethanesulfonyloxy)bicyclo[2.2.1]hept-5-ene-2,3-dicarboxylmide, N-(nonafluoro-n-butanesulfonyloxy)bicyclo[2.2.1]hept-5-ene-2,3-dicarboxylmide, N-(perfluoro-n-octanesulfonyloxy)bicyclo[2.2.1]hept-5-ene-2,3-dicarboxylmide, N-(2-bicyclo[2.2.1]hept-2-yl-1,1,2,2-tetrafluoroethanesulfonyloxy) bicyclo[2.2.1]hept-5-ene-2,3-dicarboxylmide, N-(2-(3-tetracyclo[4.4.0.1^{2,5}.1^{7,10}]dodecanyl)-1,1-difluoroethanesulfonyloxy) bicyclo[2.2.1]hept-5-ene-2,3-dicarboxylmide, and N-(camphorsulfonyloxy)bicyclo[2.2.1]hept-5-ene-2,3-dicarboxylmide can be given.

These acid generators (B) may be used either individually, or in a combination of two or more.

The amount of the acid generator (B) to be used is usually 0.1 to 30 parts by mass, preferably 0.1 to 20 parts by mass, and more preferably 0.1 to 15 parts by mass, based on 100 parts by mass of the polymer (A) from the viewpoint of ensuring sensitivity and resolution as a resist. If the amount of the acid generator is less than 0.1 part by mass, sensitivity and resolution tend to decrease. If more than 30 parts by mass, transparency to radiation tends to decrease, which makes it difficult to obtain a rectangular resist pattern.

### [3] Solvent (C)

An organic solvent is preferably used as the solvent (C). Usually, the components are dissolved or dispersed in the organic solvent.

As the organic solvent (C), at least one solvent selected from the group consisting of alcohol solvents, ketone solvents, amide solvents, ether solvents, ester solvents, aliphatic hydrocarbon solvents, aromatic solvents, and halogen-containing solvents can be used.

Examples of an alcohol solvent include monohydric alcohols such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; polyhydric alcohol solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, and tripropylene glycol;

polyhydric alcohol partial ether solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, and dipropylene glycol monopropyl ether; and the like.

These alcohol solvents may be used either individually, or in a combination of two or more.

As examples of a ketone solvent, acetone, methyl ethyl ketone, methyl n-propyl ketone, methyl n-butyl ketone, diethyl ketone, methyl i-butyl ketone, methyl n-pentyl ketone, ethyl n-butyl ketone, methyl n-hexyl ketone, di-1-butyl ketone, trimethylnonanone, cyclopentanone, cyclohexanone, cycloheptanone, cyclooctanone, 2-hexanone, methylcyclohexanone, 2,4-pentanedione, acetonylacetone, diacetone alcohol, acetophenone, fenchone, and the like can be given. These ketone solvents may be used either individually, or in a combination of two or more.

As examples of an amide solvent, nitrogen-containing solvents such as N,N-dimethylimidazolidinone, N-methylformamide, N,N-dimethylformamide, N,N-diethylformamide, acetamide, N-methylacetamide, N,N-dimethylacetamide, N-methylpropioneamide, and N-methylpyrrolidone can be given. These amide solvents may be used either individually, or in a combination of two or more.

As examples of an ether solvent, ethyl ether, i-propyl ether, n-butyl ether, n-hexyl ether, 2-ethylhexyl ether, ethylene oxide, 1,2-propylene oxide, dioxolane, 4-methyl dioxolane, dioxane, dimethyl dioxane, ethylene glycol monomethyl ether, ethylene glycol dimethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol dimethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, tripropylene glycol monomethyl ether, tetrahydrofuran, 2-methyltetrahydrofuran, diphenyl ether, and anisole can be given. These ether solvents may be used either individually, or in a combination of two or more.

Examples of an ester solvent include diethyl carbonate, propylene carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxy triglycol acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate. These ester solvents may be used either individually, or in a combination of two or more.

Examples of an aliphatic hydrocarbon solvent include n-pentane, i-pentane, n-hexane, i-hexane, n-heptane, i-heptane, 2,2,4-trimethylpentane, n-octane, i-octane, cyclohexane, and methylcyclohexane. These aliphatic hydrocarbon solvents may be used either individually, or in a combination of two or more.

As examples of an aromatic hydrocarbon solvent, benzene, toluene, xylene, ethylbenzene, trimethylbenzene, methylethylbenzene, n-propylbenzene, i-propylbenzene, diethylbenzene, i-butylbenzene, triethylbenzene, di-1-propylbenzene, n-amylnaphthalene, and trimethylbenzene can be given. These aromatic hydrocarbon solvents may be used either individually, or in a combination of two or more.

As examples of a halogen-containing solvent, dichloromethane, chloroform, fluorocarbon, chlorobenzene, and dichlorobenzene can be given. These halogen-containing solvents may be used either individually, or in a combination of two or more.

Among these solvents (C), organic solvents having a boiling point of 170° C. or less, particularly one or more solvents selected from alcohol solvents, ketone solvents, and ester solvents are preferable.

This solvent may be the same solvent as is used for synthesis of the polymer (A), or the solvent may be replaced by a desired organic solvent after completion of the synthesis of the polymer (A).

### [4] Additives

Additives such as an organic polymer, an acid diffusion controller, a surfactant, and the like may be added to the negative-tone radiation-sensitive composition according to the embodiment of the present invention.

### [4-1] Organic Polymer

Any organic polymer which can be decomposed by application of high energy rays or heat can be used without a particular limitation.

As examples of the organic polymer, a polymer having a sugar chain structure, a vinyl amide polymer, a (meth)acrylic polymer, an aromatic vinyl compound polymer, a dendolimer, a polyimide, a polyamic acid, a polyarylene, a polyamide, a polyquinoxaline, a polyoxadizole, a fluorine-containing polymer, and a polymer having a polyalkylene oxide structure can be given.

As the polyalkylene oxide structure, a polymethylene oxide structure, a polyethylene oxide structure, a polypropylene oxide structure, a polytetramethylene oxide structure, a polybutylene oxide structure, and the like can be given. As specific examples of a compound having a polyalkylene oxide structure, ether compounds such as polyoxymethylene alkyl ether, polyoxyethylene alkyl ether, polyoxyethylene alkylphenyl ether, polyoxyethylene sterol ether, polyoxyethylene lanolin derivatives, ethylene oxide derivatives of alkylphenol formalin condensate, polyoxyethylene polyoxypropylene block copolymers, and polyoxyethylene polyoxypropylene alkyl ethers; ether-ester compounds such as polyoxyethylene glyceride, polyoxyethylene sorbitan fatty acid ester, polyoxyethylene sorbitol fatty acid ester, and polyoxyethylene fatty acid alkanolamide sulfate; and ether-ester compounds such as polyethylene glycol fatty acid ester, ethylene glycol fatty acid ester, fatty acid monoglyceride, polyglycerol fatty acid ester, sorbitan fatty acid ester, propylene glycol fatty acid ester, and sucrose fatty acid ester can be given.

As a polyoxyethylene polyoxypropylene block copolymer, compounds having the following block structure can be given.

—(X′)₁—(Y′)ₘ—

—(X′)₁—(Y′)ₘ—(X′)ₙ—

wherein X′ represents a group —CH₂CH₂O—, Y′ represents a group —CH₂CH(CH₃)O—, 1 represents an integer from 1 to 90, m represents an integer from 10 to 99, and n represents an integer from 0 to 90.

Of these, the ether compounds such as a polyoxyethylene alkyl ether, a polyoxyethylene-polyoxypropylene block copolymer, a polyoxyethylene polyoxypropylene alkyl ether, a polyoxyethylene glyceride, a polyoxyethylene sorbitan fatty acid ester, and a polyoxyethylene sorbitol fatty acid ester are preferable.

These organic polymers may be used either individually, or in a combination of two or more.

### [4-2] Acid Diffusion Controller (D)

The acid diffusion controller (D) controls diffusion of an acid generated from the acid generator upon irradiation in the resist film and suppresses undesired chemical reactions in the non-irradiated area.

The addition of the acid diffusion controller improves resolution as a resist and prevents the line width of the resist pattern from changing due to variation of post-exposure delay (PED) from exposure to development, whereby a composition with remarkably superior process stability can be obtained. As the acid diffusion controller, nitrogen-containing organic compounds of which the basicity does not change during irradiation or heating when forming a resist pattern are preferable.

As examples of the nitrogen-containing organic compound, tertiary amine compounds, amide group-containing compounds, quaternary ammonium hydroxide compounds, and nitrogen-containing heterocyclic compounds can be given. Examples of the tertiary amine compound include tri(cyclo)alkylamines such as triethylamine, tri-n-propylamine, tri-n-butylamine, tri-n-pentylamine, tri-n-hexylamine, tri-n-heptylamine, tri-n-octylamine, tri-n-nonyl amine, tri-n-decylamine, cyclohexyl dimethylamine, dicyclohexyl methylamine, and tricyclohexylamine; aromatic amines such as aniline, N-methylaniline, N,N-dimethylaniline, 2-methylaniline, 3-methylaniline, 4-methylaniline, 4-nitroaniline, 2,6-dimethylaniline, 2,6-diisopropylaniline, diphenylamine, triphenylamine, and naphthylamine; alkanolamines such as triethanolamine and diethanolaniline; N,N,N′,N′-tetramethylethylenediamine, N,N,N′,N′-tetrakis(2-hydroxypropyl)ethylenediamine, 1,3-bis[1-(4-aminophenyl)-1-methylethyl]benzene tetramethylenediamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis[1-(4-aminophenyl)-1-methylethyl]benzene, 1,3-bis[1-(4-aminophenyl)-1-methylethyl]benzene, bis(2-dimethylaminoethyl)ether, and bis(2-diethylaminoethyl)ether.

As examples of the amide group-containing compounds, in addition to N-t-butoxycarbonyl group-containing amino compounds such as N-t-butoxycarbonyldi-n-octylamine, N-t-butoxycarbonyldi-n-nonylamine, N-t-butoxycarbonyldi-n-decylamine, N-t-butoxycarbonyldicyclohexylamine, N-t-butoxycarbonyl-1-adamantylamine, N-t-butoxycarbonyl-N-methyl-1-adamantylamine, N,N-di-t-butoxycarbonyl-1-adamantylamine, N,N-di-t-butoxycarbonyl-N-methyl-1-adamantylamine, N-t-butoxycarbonyl-4,4′-diaminodiphenylmethane, N,N′-di-t-butoxycarbonylhexamethylenediamine, N,N,N′N′-tetra-t-butoxycarbonylhexamethylenediamine, N,N′-di-t-butoxycarbonyl-1,7-diaminoheptane, N,N′-di-t-butoxycarbonyl-1,8-diaminooctane, N,N′-di-t-butoxycarbonyl-1,9-diaminononane, N,N′-di-t-butoxycarbonyl-1,10-diaminodecane, N,N′-di-t-butoxycarbonyl-1,12-diaminododecane, N,N′-di-t-butoxycarbonyl-4,4′-diaminodiphenylmethane, N-t-butoxycarbonylbenzimidazole, N-t-butoxycarbonyl-2-methylbenzimidazole, N-t-butoxycarbonyl-2-phenylbenzimidazole, N-t-butoxycarbonyl-pyrrolidine, N-t-butoxycarbonyl-piperidine, N-t-butoxycarbonyl-4-hydroxy-piperidine, and N-t-butoxycarbonylmorpholine, formamide, N-methylformamide, N,N-dimethylformamide, acetamide, N-methylacetamide, N,N-dimethylacetamide, propionamide, benzamide, pyrrolidone, N-methylpyrrolidone, and the like can be given.

As examples of the quaternary ammonium hydroxide compound, tetramethylammonium hydroxide, tetraethylammonium hydroxide, tetra-n-propylammonium hydroxide, and tetra-n-butylammonium hydroxide can be given.

Examples of the nitrogen-containing heterocyclic compounds include imidazoles such as imidazole, 4-methylimidazole, 1-benzyl-2-methylimidazole, 4-methyl-2-phenylimidazole, benzimidazole, and 2-phenylbenzimidazole; pyridines such as pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotinic acid, nicotinamide, quinoline, 4-hydroxyquinoline, 8-oxyquinoline, and acridine; piperazines such as piperazine, 1-(2-hydroxyethyl)piperazine; and pyrazine, pyrazole, pyridazine, quinoxaline, purine, pyrrolidine, piperidine, 3-piperidino-1,2-propanediol, morpholine, 4-methylmorpholine, 1,4-dimethylpiperazine, and 1,4-diazabicyclo[2.2.2]octane.

Of these acid diffusion controllers, tertiary amine compounds, amide-containing compounds, and nitrogen-containing heterocyclic compounds are preferable. Among the amide group-containing compounds, an N-t-butoxycarbonyl group-containing amino compound is preferable and among the nitrogen-containing heterocyclic compounds, imidazole is preferable.

These acid diffusion controllers may be used either individually, or in a combination of two or more.

The amount of the acid diffusion controller to be added is usually 15 parts by mass or less, preferably 10 parts by mass or less, and still more preferably 5 parts by mass or less, based on 100 parts by mass of the polymer (A). If the amount of the acid diffusion controller exceeds 15 parts by mass, sensitivity as a resist and developability of the irradiated area tend to decrease. If the amount is less than 0.001 part by mass, the pattern shape or dimensional accuracy as a resist may decrease depending on the processing conditions.

### [4-3] Surfactants

The surfactant improves applicability, striation, developability, and the like. As examples of the surfactant, a nonionic surfactant, an anionic surfactant, a cationic surfactant, an amphoteric surfactant, a silicon-containing surfactant, a polyalkylene oxide surfactant, a fluorine-containing surfactant, and a poly(meth)acrylate surfactant can be given. As specific examples of surfactants, nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate; and commercially available products such as SH8400 FLUID (manufactured by Toray Dow Corning Silicone Co.), KP341 (manufactured by Shin-Etsu Chemical Co., Ltd.), Polyflow No. 75, No. 95 (manufactured by Kyoeisha Chemical Co., Ltd.), EFTOP EF301, EF303, EF352 (manufactured by JEMCO, Inc.), MEGAFAC F171, F173 (manufactured by Dainippon Ink and Chemicals, Inc.), Fluorad FC430, FC431 (manufactured by Sumitomo 3M Ltd.), Asahi Guard AG710, Surflon 5382, SC101, SC102, SC103, SC104, SC105, SC106 (manufactured by Asahi Glass Co., Ltd.), and the like can be given. Of these, fluorine-containing surfactants and silicon-containing surfactants are preferable. These surfactants can be used either individually, or in a combination of two or more.

The amount of the surfactants is usually 0.00001 to 1 part by mass per 100 parts by mass of the polymer (A).

### [5] Preparation of Negative-Tone Radiation-Sensitive Composition

The negative-tone radiation-sensitive composition according to the embodiment of the present invention can be obtained by mixing the polymer (A), the acid generator (B), the solvent (C), and the optionally used other additives. Either one type of polymer (A) may be used or two or more types of polymers (A) may be used in combination. The solid content of the negative-tone radiation-sensitive composition is appropriately adjusted according to the purpose of use in a range, for example, of 1 to 50 mass %, and particularly 10 to 40 mass %. If the solid content is 1 to 50 mass %, an appropriate film thickness can be ensured.

### [6] Pattern Forming Method

There are two methods of forming a cured pattern according to an embodiment of the present invention. One is a method for forming a cured pattern consisting only of one shape such as a trench or a hole (hereinafter referred to from time to time as “pattern forming method (I)”) and the other is a method for forming a cured pattern having a dual damascene structure which has shapes of both a trench and a hole (hereinafter referred to from time to time as “pattern forming method (II)”).

### [6-1] Pattern Forming Method (I)

The pattern forming method (I) includes (I-1) applying the negative-tone radiation-sensitive composition to form a film (hereinafter referred to as “step (I-1)”), (I-2) baking the resulting film (hereinafter referred to as “step (I-2)”), (I-3) exposing the baked film (hereinafter referred to as “step (I-3)”), (I-4) developing the exposed film using a developer to form a negative-tone pattern (hereinafter referred to as “step (I-4)”), and (I-5) applying at least one of high energy rays and heat to the resulting negative-tone pattern to form a cured pattern (hereinafter referred to as “step (I-5)”).

In the step (I-1), a negative-tone radiation-sensitive composition is applied to a substrate to form a film. The above description of the negative-tone radiation-sensitive composition can be applied as is to the negative-tone radiation-sensitive composition used in the pattern forming method. As the method of applying the negative-tone radiation-sensitive composition, rotational coating, cast coating, roll coating, and the like can be given. An amount of the composition to make a film with a specified thickness is applied

As examples of the substrate, wafers and the like covered with a Si-containing layer such as Si, SiO₂, SiN, SiC, and SiCN can be given. In order to bring out the potential of the negative-tone radiation-sensitive composition to the maximum extent, an organic or inorganic antireflection film may be previously formed on the substrate as disclosed in JP-B-6-12452 (JP-A-59-93448), for example.

In the step (I-2), the film is baked (hereinafter referred to as “PB”), whereby the solvent is vaporized from the film. The PB heating conditions are appropriately selected according to the composition, usually a range of 60 to 150° C., and preferably 70 to 120° C.

In the step (I-3), specified areas of the baked film are exposed so that a specified negative-tone pattern can be obtained.

As the radiation used for exposure, visible rays, ultraviolet rays, deep ultraviolet rays, X-rays, charged particle beams such as electron beams, and the like are appropriately selected depending on the type of acid generator. It is particularly preferable to use deep ultraviolet rays represented by an ArF excimer laser (wavelength: 193 nm) and KrF excimer laser (wavelength: 248 nm), and electron beams.

The exposure conditions such as an amount of exposure are appropriately determined according to the composition of the radiation-sensitive composition, types of additives, and the like.

In the embodiment of the present invention, it is preferable to perform post-exposure bake (PEB) after the exposure. The PEB ensures a smooth crosslinking reaction of the polymer in the composition. The PEB heating conditions are appropriately selected according to the composition, usually a range of 30 to 200° C., and preferably 50 to 170° C.

A desired negative-tone pattern can be formed by developing the exposed film in the step (I-4).

As examples of the developer used for development, alkaline aqueous solutions prepared by dissolving at least one of alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide, pyrrole, piperidine, choline, 1,8-diazabicyclo-[5.4.0]-7-undecene, and 1,5-diazabicyclo-[4.3.0]-5-nonene are preferable. Of these, tetramethylammonium hydroxide is particularly preferable.

Organic solvents or the like may be added to the alkaline aqueous solution developer. As examples of the organic solvent, ketones such as acetone, methyl ethyl ketone, methyl i-butyl ketone, cyclopentanone, cyclohexanone, 3-methylcyclopentanone, and 2,6-dimethylcyclohexanone; alcohols such as methylalcohol, ethylalcohol, n-propylalcohol, i-propylalcohol, n-butylalcohol, t-butylalcohol, cyclopentanol, cyclohexanol, 1,4-hexanediol, and 1,4-hexanedimethylol; ethers such as tetrahydrofuran and dioxane; esters such as ethyl acetate, n-butyl acetate, and i-amyl acetate; aromatic hydrocarbons such as toluene and xylene; phenol; acetonylacetone; and dimethylformamide can be given. These organic solvents may be used either individually, or in a combination of two or more.

The amount of the organic solvent to be used is preferably 100 vol % or less of the alkaline aqueous solution. If the amount of the organic solvent is more than 100 vol %, the developability may decrease and exposed areas remaining undeveloped may increase.

In addition, an appropriate amount of a surfactant and the like may be added to the developer containing the alkaline aqueous solution.

After development using an alkaline aqueous solution developer, the resist film is generally washed with water and dried.

In the step (I-5), a certain specific treatment is applied to the negative-tone pattern to form a cured pattern.

The applicable specific treatment includes a heat treatment, high energy irradiation such as electron beams and ultraviolet rays, a plasma treatment, and the like. Among these, a heat treatment and high energy irradiation are preferable. These treatments may be used in combination.

When a heat treatment is applied, the negative-tone pattern is heated preferably at 80 to 450° C., and more preferably at 300 to 450° C. in an inert gas atmosphere or under reduced pressure. A hot plate, an oven, a furnace, and the like may be used for heating.

In order to control the curing speed of the negative-tone pattern, the film may be heated stepwise, heating may be carried out in a nitrogen atmosphere, air atmosphere, or oxygen atmosphere, or reduced pressure may be used, if necessary. A silica-based film (cured pattern) with a low relative dielectric constant can be produced by these steps. The relative dielectric constant of the film can be lowered by the above treatments.

### [6-2] Pattern Forming Method (II)

The pattern forming method (II) according to the embodiment of the present invention includes (II-1) applying the negative-tone radiation-sensitive composition to a substrate, followed by exposure and development to form a negative-tone hole pattern substrate having a negative-tone hole pattern (hereinafter referred to from time to time as “step (II-1)”), (II-2) applying the negative-tone radiation-sensitive composition to the resulting negative-tone hole pattern substrate, followed by exposure and development to form a negative-tone trench pattern on the negative-tone hole pattern substrate, thereby forming a negative-tone dual damascene pattern substrate (hereinafter referred to from time to time as “step (II-2)”), and (II-3) applying at least one of high energy rays and heat to the resulting negative-tone dual damascene pattern substrate to form a cured pattern having a dual damascene structure (hereinafter referred to from time to time as “step (II-3)”).

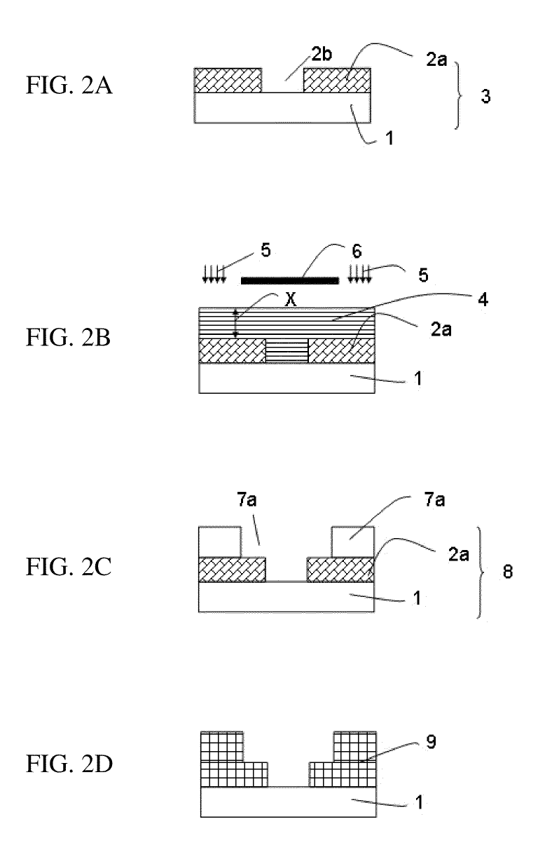

In the above step (II-1), a negative-tone hole pattern substrate having a negative-tone hole pattern is prepared by appropriately performing the steps (I-1) to (I-4) of the above-mentioned pattern forming method (I) (FIG. 2A). The thickness of the negative-tone hole pattern obtained in this step is preferably 30 to 1000 nm.

In the step (II-2), the negative-tone radiation-sensitive composition is applied onto the negative-tone hole pattern substrate obtained in the above step (II-1) to form a film of the negative-tone radiation-sensitive composition on the negative-tone hole pattern substrate (see FIG. 2B). As the method of applying the negative-tone radiation-sensitive composition and the substrate used here, the same method and substrate described in the above step (I-1) can be used. In forming the film of the negative-tone radiation-sensitive composition, the film may be baked in the same manner as in the above step (I-2). The thickness of the film of the negative-tone radiation-sensitive composition (x in FIG. 2B) obtained in this step is preferably 30 to 1000 nm.

The film of the negative-tone radiation-sensitive composition is processed in the same manner as in the above steps (I-3) and (I-4) to obtain a negative-tone trench pattern on the negative-tone hole pattern substrate, followed by formation of a negative-tone dual damascene pattern substrate (see FIG. 2C).

In the step (II-3), the negative-tone dual damascene pattern substrate obtained in the step (II-2) is processed in the same manner as in the above step (I-5) to obtain a cured pattern having a dual damascene structure (see FIG. 2D).

### [7] Relative Dielectric Constant of Cured Pattern

The relative dielectric constant of the cured pattern obtained using the negative-tone radiation-sensitive composition according to the embodiment of the present invention is preferably 1.5 to 3.0, and more preferably 1.5 to 2.8. When the relative dielectric constant is in the range of 1.5 to 3.0, the cured pattern can be preferably used as a low-relative-dielectric-constant material. Therefore, the cured pattern is useful as a microfabrication material for semiconductor devices such as LSI, system LSI, DRAM, SDRAM, RDRAM, and D-RDRAM. In addition, the cure pattern is an excellent interlayer dielectric material, particularly for producing semiconductor devices including a copper damascene process.

The relative dielectric constant may be adjusted by changing the molecular weight of the resin and the curing conditions.

### EXAMPLES

The embodiments of the present invention are further described below by way of examples. However, these examples should not be construed as limiting the present invention. In the examples, “parts” and “%” refer respectively to “parts by mass” and “mass %”, unless otherwise indicated.

### Example Group I

### [1] Preparation of Siloxane Resin Solution (A)

Resin solutions Nos. 7 to 21 of a silicon-containing resin (A) were prepared as shown in the following Synthesis Examples 1 to 11 and Comparative Synthesis Examples 1 to 3.

The weight average molecular weight (Mw) of the silicon-containing resin obtained in each synthesis example was measured by the following method.

### <Measurement of Weight Average Molecular Weight (Mw)>

The weight average molecular weight (Mw) of the siloxane resin obtained in each synthesis example was measured by size exclusion chromatography (SEC) under the following conditions.

Sample: A sample was prepared by dissolving 0.1 g of a hydrolysis-condensate in 100 cc of a 10 mmol/l LiBr—H₃PO₄ solution in 2-methoxyethanol.
Standard sample: Polyethylene oxide manufactured by Wako Pure Chemical Industries, Ltd.
Instrument: High-performance GPC (“HLC-8120GPC”) manufactured by Tosoh Corp.
Column: TSK-GEL SUPER AWM-H (length: 15 cm) manufactured by Tosoh Corp., three columns connected in series.
Measurement temperature: 40° C.
Flow rate: 0.6 ml/min
Detector: RI installed in high performance GPC (“HLC-8120GPC”) manufactured by Tosoh Corp.

### Comparative Synthesis Example 1

### Resin Solution No. 7

A nitrogen-replaced three-necked quartz flask was charged with 1.45 g of a 20% maleic acid aqueous solution and 94.9 g of ultrapure water, and the mixture was heated to 75° C. After the dropwise addition of a mixed solution of 49.2 g (0.323 mol) of tetramethoxysilane, 102.7 g (0.754 mol) of methyltrimethoxysilane, and 1.85 g of ethoxypropanol over one hour, the mixture was stirred at 75° C. for two hours. The reaction solution was allowed to cool to room temperature and concentrated under reduced pressure to a solid concentration of 25% to obtain 270 g of a silicon-containing resin solution (Resin solution No. 7). The resin in the solution is referred to as silicon-containing resin (A-7). Refer to the following formula (A-7) for the units forming the resin. The ratio (a:b) of the monomer units in the silicon-containing resin (A-7) was 30:70 (mol %), and the Mw of the resin was 9100.

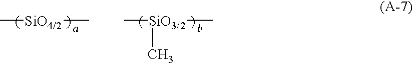

### Synthesis Example 1

### Resin Solution No. 8

A nitrogen-replaced three-necked quartz flask was charged with 1.39 g of a 20% maleic acid aqueous solution and 90.99 g of ultrapure water, and the mixture was heated to 75° C. After the dropwise addition of a mixed solution of 32.4 g (0.213 mol) of tetramethoxysilane, 116.1 g (0.852 mol) of methyltrimethoxysilane, and 9.10 g of ethoxypropanol over one hour, the mixture was stirred at 75° C. for two hours. The reaction solution was allowed to cool to room temperature and concentrated under reduced pressure to a solid concentration of 25% to obtain 270 g of a silicon-containing resin solution (Resin solution No. 8). The resin in the solution is referred to as silicon-containing resin (A-8). Refer to the following formula (A-8) for the units forming the resin. The ratio (a:b) of the monomer units in the silicon-containing resin (A-8) was 20:80 (mol %), and the Mw was 8800.

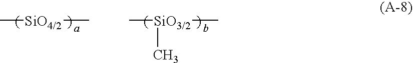

### Synthesis Example 2

### Resin Solution No. 9

A nitrogen-replaced three-necked quartz flask was charged with 2.14 g of a 20% maleic acid aqueous solution and 139.6 g of ultrapure water, and the mixture was heated to 75° C. After the dropwise addition of a mixed solution of 25.7 g (0.169 mol %) of tetramethoxysilane, 206.7 g (1.52 mol) of methyltrimethoxysilane, and 25.9 g of ethoxypropanol over one hour, the mixture was stirred at 75° C. for two hours. The reaction solution was allowed to cool to room temperature and concentrated under reduced pressure to a solid concentration of 25% to obtain 440 g of a silicon-containing resin solution (Resin solution No. 9). The resin in the solution is referred to as silicon-containing resin (A-9). Refer to the following formula (A-9) for the units forming the resin. The ratio (a:b) of the monomer units in the silicon-containing resin (A-9) was 10:90 (mol %), and the Mw was 8500.

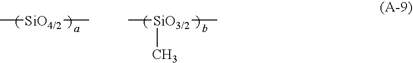

### Synthesis Example 3

### Resin Solution No. 10

A nitrogen-replaced three-necked quartz flask was charged with 2.14 g of a 20% maleic acid aqueous solution and 139.6 g of ultrapure water, and the mixture was heated to 65° C. After the dropwise addition of a mixed solution of 25.7 g (0.169 mol %) of tetramethoxysilane, 206.7 g (1.52 mol) of methyltrimethoxysilane, and 25.9 g of ethoxypropanol over one hour, the mixture was stirred at 65° C. for four hours. The reaction solution was allowed to cool to room temperature and concentrated under reduced pressure to a solid concentration of 25% to obtain 430 g of a silicon-containing resin solution (Resin solution No. 10). The resin in the solution is referred to as silicon-containing resin (A-10). Refer to the following formula (A-10) for the units forming the resin. The ratio (a:b) of the monomer units in the silicon-containing resin (A-10) was 10:90 (mol %), and the Mw was 8300.

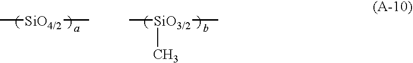

### Synthesis Example 4

### Resin Solution No. 11

A nitrogen-replaced three-necked quartz flask was charged with 1.28 g of a 20% maleic acid aqueous solution and 83.52 g of ultrapure water, and the mixture was heated to 75° C. After the dropwise addition of a mixed solution of 142.1 g (1.04 mol) of methyltrimethoxysilane and 23.1 g of ethoxypropanol over one hour, the mixture was stirred at 75° C. for two hours. The reaction solution was allowed to cool to room temperature and concentrated under reduced pressure to a solid concentration of 25% to obtain 270 g of a silicon-containing resin solution (Resin solution No. 11). The resin in the solution is referred to as silicon-containing resin (A-11). Refer to the following formula (A-11) for the units forming the resin. The Mw of the silicon-containing resin (A-11) was 8000.

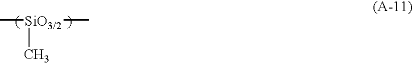

### Synthesis Example 5

### Resin Solution No. 12

A nitrogen-replaced three-necked quartz flask was charged with 1.39 g of a 20% maleic acid aqueous solution and 90.99 g of ultrapure water, and the mixture was heated to 60° C. After the dropwise addition of a mixed solution of 32.4 g (0.213 mol) of tetramethoxysilane, 116.1 g (0.852 mol) of methyltrimethoxysilane, and 9.10 g of ethoxypropanol over one hour, the mixture was stirred at 60° C. for two hours. The reaction solution was allowed to cool to room temperature and concentrated under reduced pressure to a solid concentration of 25% to obtain 270 g of a silicon-containing resin solution (Resin solution No. 12). The resin in the solution is referred to as silicon-containing resin (A-12). Refer to the following formula (A-12) for the units forming the resin.

The ratio (a:b) of the monomer units in the silicon-containing resin (A-12) was 20:80 (mol %), and the Mw was 5100.

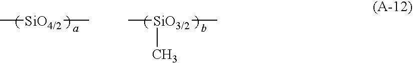

### Synthesis Example 6

### Resin Solution No. 13

A nitrogen-replaced three-necked quartz flask was charged with 1.33 g of a 20% maleic acid aqueous solution and 87.22 g of ultrapure water, and the mixture was heated to 60° C. After the dropwise addition of a mixed solution of 16.0 g (0.105 mol) of tetramethoxysilane, 129.2 g (0.948 mol) of methyltrimethoxysilane, and 16.2 g of ethoxypropanol over one hour, the mixture was stirred at 60° C. for two hours. The reaction solution was allowed to cool to room temperature and concentrated under reduced pressure to a solid concentration of 25% to obtain 270 g of a silicon-containing resin solution (Resin solution No. 13). The resin in the solution is referred to as silicon-containing resin (A-13). Refer to the following formula (A-13) for the units forming the resin.

The ratio (a:b) of the monomer units in the silicon-containing resin (A-13) was 10:90 (mol %), and the Mw was 4800.

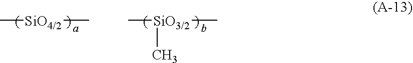

### Synthesis Example 7

### Resin Solution No. 14

A nitrogen-replaced three-necked quartz flask was charged with 1.28 g of a 20% maleic acid aqueous solution and 83.52 g of ultrapure water, and the mixture was heated to 60° C. After the dropwise addition of a mixed solution of 142.1 g (1.04 mol) of methyltrimethoxysilane and 23.1 g of ethoxypropanol over one hour, the mixture was stirred at 60° C. for two hours. The reaction solution was allowed to cool to room temperature and concentrated under reduced pressure to a solid concentration of 25% to obtain 270 g of a silicon-containing resin solution (Resin solution No. 14). The resin in the solution is referred to as silicon-containing resin (A-14). Refer to the following formula (A-14) for the units forming the resin. The Mw of the silicon-containing resin (A-14) was 4500.

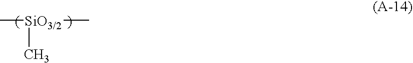

### Synthesis Example 8

### Resin Solution No. 15-1

A nitrogen-replaced three-necked quartz flask was charged with 2.14 g of a 20% maleic acid aqueous solution and 139.6 g of ultrapure water, and the mixture was heated to 75° C. After the dropwise addition of a mixed solution of 25.7 g (0.169) of tetramethoxysilane, 206.7 g (1.52 mol) of methyltrimethoxysilane, and 25.9 g of ethoxypropanol over one hour, the mixture was stirred at 75° C. for eight hours. The reaction solution was allowed to cool to room temperature and concentrated under reduced pressure to a solid concentration of 25% to obtain 440 g of a silicon-containing resin solution (Resin solution No. 15-1). The resin in the solution is referred to as silicon-containing resin (A-15-1). Refer to the following formula (A-15) for the units forming the resin. The ratio (a:b) of the monomer units in the silicon-containing resin (A-15-1) was 10:90 (mol %), and the Mw was 13000.

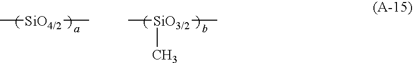

### Comparative Synthesis Example 2

### Resin Solution No. 15-2

A nitrogen-replaced three-necked quartz flask was charged with 2.14 g of a 20% maleic acid aqueous solution and 139.6 g of ultrapure water, and the mixture was heated to 75° C. After the dropwise addition of a mixed solution of 25.7 g (0.169) of tetramethoxysilane, 206.7 g (1.52 mol) of methyltrimethoxysilane, and 25.9 g of ethoxypropanol over one hour, the mixture was stirred at 75° C. for sixteen hours. The reaction solution was allowed to cool to room temperature and concentrated under reduced pressure to a solid concentration of 25% to obtain 440 g of a silicon-containing resin solution (Resin solution No. 15-2). The resin in the solution is referred to as silicon-containing resin (A-15-2). Refer to the formula (A-15) for the units forming the resin. The ratio (a:b) of the monomer units in the silicon-containing resin (A-15-2) was 10:90 (mol %), and the Mw was 300,000.

### Comparative Synthesis Example 3

### Resin Solution No. 16

A nitrogen-replaced three-necked quartz flask was charged with 2.14 g of a 20% maleic acid aqueous solution and 139.6 g of ultrapure water, and the mixture was heated to 50° C. After the dropwise addition of a mixed solution of 25.7 g (0.169 mol) of tetramethoxysilane, 206.7 g (1.52 mol) of methyltrimethoxysilane, and 25.9 g of ethoxypropanol over one hour, the mixture was stirred at 50° C. for two hours. The reaction solution was allowed to cool to room temperature and concentrated under reduced pressure to a solid concentration of 25% to obtain 440 g of a silicon-containing resin solution (Resin solution No. 16). The resin in the solution is referred to as silicon-containing resin (A-16). Refer to the following formula (A-16) for the units forming the resin. The ratio (a:b) of the monomer units in the silicon-containing resin (A-16) was 10:90 (mol %), and the Mw was 3500.

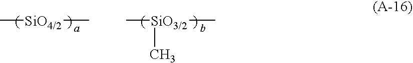

### Synthesis Example 8

### Resin Solution No. 17

A three-necked quartz flask equipped with a condenser was charged with 37.3 g of a 25% tetramethylammonium hydroxide aqueous solution, 156.3 g of ultrapure water, and 234.4 g of ethanol. The mixture was dissolved to obtain a solution (17-1). A mixed solution (17-2) was prepared from 22.2 g (0.107 mol) of tetraethoxysilane, 58.0 g (0.426 mol) of methyltrimethoxysilane, and 191.8 g of ethanol and filled in a dropping funnel.

After dropwise addition of the solution (17-2) to the solution (17-1) while stirring the latter at 60° C. over one hour, the mixture was stirred at 60° C. for one hour. The reaction solution was allowed to cool to room temperature. After addition of 525 g of butyl acetate and 37.6 g of a 20% maleic acid aqueous solution, the mixture was washed three times with 175 g of ultrapure water and concentrated under reduced pressure to a solid concentration of 25% to obtain 125 g of a silicon-containing resin solution (Resin solution No. 17). The resin in the solution is referred to as silicon-containing resin (A-17). Refer to the following formula (A-17) for the units forming the resin. The ratio (a:b) of the monomer units in the silicon-containing resin (A-17) was 20:80 (mol %), and the Mw was 9500.

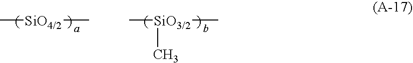

### Synthesis Example 9

### Resin Solution No. 18-1

A nitrogen-replaced three-necked quartz flask was charged with 1.20 g of a 20% maleic acid aqueous solution and 57.01 g of ultrapure water, and the mixture was heated to 75° C. After the dropwise addition of a mixed solution of 14.4 g (0.0946 mol) of tetramethoxysilane, 102.8 g (0.755 mol) of methyltrimethoxysilane, 14.2 g (0.0946 mol) of ethyltrimethoxysilane, and 10.4 g of ethoxypropanol over one hour, the mixture was stirred at 75° C. for two hours. The reaction solution was allowed to cool to room temperature and concentrated under reduced pressure to a solid concentration of 25% to obtain 250 g of a silicon-containing resin solution (Resin solution No. 18-1). The resin in the solution is referred to as silicon-containing resin (A-18-1). Refer to the following formula (A-18) for the units forming the resin. The ratio of the monomer units a:b:c in the silicon-containing resin (A-18-1) was 10:80:10 (mol %), and the Mw was 8600.

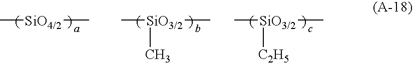

### Synthesis Example 10

### Resin Solution No. 18-2

A nitrogen-replaced three-necked quartz flask was charged with 3.24 g of a 20% maleic acid aqueous solution and 68.75 g of ultrapure water, and the mixture was heated to 75° C. After the dropwise addition of a mixed solution of 25.1 g (0.165 mol) of tetramethoxysilane, 33.7 g (0.247 mol) of methyltrimethoxysilane, 62.0 g (0.413 mol) of ethyltrimethoxysilane, and 7.21 g of ethoxypropanol over one hour, the mixture was stirred at 75° C. for two hours. The reaction solution was allowed to cool to room temperature and concentrated under reduced pressure to a solid concentration of 25% to obtain 240 g of a silicon-containing resin solution (Resin solution No. 18-2). The resin in the solution is referred to as silicon-containing resin (A-18-2). Refer to the formula (A-18) for the units forming the resin. The ratio of the monomer units a:b:c in the silicon-containing resin (A-18-2) was 20:30:50 (mol %), and the Mw was 7600.

### Synthesis Example 11

### Resin Solution No. 19

A nitrogen-replaced three-necked quartz flask was charged with 0.77 g of a 20% maleic acid aqueous solution and 50.11 g of ultrapure water, and the mixture was heated to 75° C. After the dropwise addition of a mixed solution of 9.53 g (0.0626 mol) of tetramethoxysilane, 68.2 g (0.501 mol) of methyltrimethoxysilane, 7.52 g (0.0626 mol) of dimethyldimethoxysilane, and 13.9 g of ethoxypropanol over one hour, the mixture was stirred at 75° C. for two hours. The reaction solution was allowed to cool to room temperature and concentrated under reduced pressure to a solid concentration of 25% to obtain 160 g of a silicon-containing resin solution (Resin solution No. 19). The resin in the solution is referred to as silicon-containing resin (A-19). Refer to the following formula (A-19) for the units forming the resin.

The ratio of the monomer units a:b:c in the silicon-containing resin (A-19) was 10:80:10 (mol %), and the Mw was 8300.

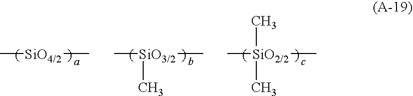

### Synthesis Example 12

### Resin Solution No. 20

A nitrogen-replaced three-necked quartz flask was charged with 2.28 g of a 20% maleic acid aqueous solution and 48.53 g of ultrapure water, and the mixture was heated to 75° C. After the dropwise addition of a mixed solution of 13.7 g (0.0901 mol) of tetramethoxysilane, 98.3 g (0.722 mol) of methyltrimethoxysilane, 22.4 g (0.0901 mol) of 3-(methacryloxy)propyltrimethoxysilane, and 14.8 g of ethoxypropanol over one hour, the mixture was stirred at 75° C. for two hours. The reaction solution was allowed to cool to room temperature and concentrated under reduced pressure to a solid concentration of 25% to obtain 270 g of a silicon-containing resin solution (Resin solution No. 20). The resin in the solution is referred to as silicon-containing resin (A-20). Refer to the following formula (A-20) for the units forming the resin.

The ratio of the monomer units a:b:c in the silicon-containing resin (A-20) was 10:80:10 (mol %), and the Mw was 8200.

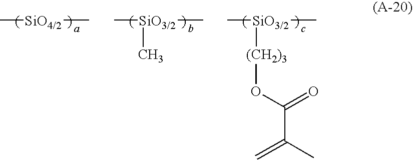

### Synthesis Example 13

### Resin Solution No. 21

A nitrogen-replaced three-necked quartz flask was charged with 2.14 g of a 20% maleic acid aqueous solution and 139.6 g of ultrapure water, and the mixture was heated to 75° C. After the dropwise addition of a mixed solution of 25.7 g (0.169 mol) of tetramethoxysilane, 206.7 g (1.52 mol) of methyltrimethoxysilane, and 25.9 g of 4-methyl-2-pentanol over one hour, the mixture was stirred at 75° C. for two hours. The reaction solution was allowed to cool to room temperature and concentrated under reduced pressure to a solid concentration of 25% to obtain 440 g of a silicon-containing resin solution (Resin solution No. 21). The resin in the solution is referred to as silicon-containing resin (A-21). Refer to the following formula (A-21) for the units forming the resin.

The ratio (a:b) of the monomer units in the silicon-containing resin (A-21) was 10:90 (mol %), and the Mw was 9900.

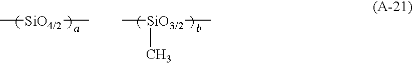

### [2] Preparation of Negative-Tone Radiation-Sensitive Composition

### Examples 1 to 18 and Comparative Examples 1 to 4

Negative-tone radiation-sensitive compositions of Examples 1 to 18 and Comparative Examples 1 to 4 were prepared by mixing the silicon-containing resin solution (A), acid generator (B), and acid diffusion controller (D) shown in Table 1 in a proportion shown in Table 1. As a solvent, propylene glycol monomethyl ether acetate (Examples 1 to 17 and Comparative Examples 1 to 4) or 4-methyl-2-pentanol (Example 18) was added in an amount to make the solid concentration of the composition become 17%.

TABLE 1

| | Silicon-containing | Silicon-containing | | Acid diffusion |
|---|---|---|---|---|
| | resin solution | resin (A) | Acid generator (C) | controller (D) |
| Examples | (type/parts) | (type/parts) | (type/parts) | (type/parts) |
| Comparative | No. 7/400 | A-7/100 | B-1/2 | D-1/0.2 |
| Examples 1 | | | | |
| Examples 1 | No. 8/400 | A-8/100 | B-1/2 | D-1/0.2 |
| Examples 2 | No. 9/400 | A-9/100 | B-1/2 | D-1/0.2 |
| Examples 3 | No. 10/400 | A-10/100 | B-1/2 | D-1/0.2 |
| Examples 4 | No. 11/400 | A-11/100 | B-1/2 | D-1/0.2 |
| Examples 5 | No. 12/400 | A-12/100 | B-1/2 | D-1/0.2 |
| Examples 6 | No. 13/400 | A-13/100 | B-1/2 | D-1/0.2 |
| Examples 7 | No. 14/400 | A-14/100 | B-1/2 | D-1/0.2 |
| Examples 8 | No. 15-1/400 | A-15-1/100 | B-1/2 | D-1/0.2 |
| Comparative | No. 15-2/400 | A-15-2/100 | B-1/2 | D-1/0.2 |
| Examples 2 | | | | |
| Comparative | No. 16/400 | A-16/100 | B-1/2 | D-1/0.2 |
| Examples 3 | | | | |
| Examples 9 | No. 17/400 | A-17/100 | B-1/2 | D-1/0.2 |
| Examples 10 | No. 18-1/400 | A-18-1/100 | B-1/2 | D-1/0.2 |
| Examples 11 | No. 18-2/400 | A-18-2/100 | B-1/2 | D-1/0.2 |
| Examples 12 | No. 19/400 | A-19/100 | B-1/2 | D-1/0.2 |
| Examples 13 | No. 20/400 | A-20/100 | B-1/2 | D-1/0.2 |
| Examples 14 | No. 7/200 | A-8/50 | B-1/2 | D-1/0.2 |
| | No. 11/200 | A-11/50 | | |
| Examples 15 | No. 8/200 | A-7/50 | B-1/2 | D-1/0.2 |
| | No. 11/200 | A-11/50 | | |
| Examples 16 | No. 9/200 | A-9/50 | B-1/2 | D-1/0.2 |
| | No. 19/200 | A-19/50 | | |
| Examples 17 | No. 18-1/200 | A-18-1/50 | B-1/2 | D-1/0.2 |
| | No. 19/200 | A-19/50 | | |
| Examples 18 | No. 21/400 | A-21/100 | B-1/2 | D-1/0.2 |
| Comparative | No. 7/400 | A-7/100 | — | D-1/0.2 |
| Examples 4 | | | | |

The acid generators (B) and the acid diffusion controllers (D) shown in Table 1 are as follows.

### <Acid Generator (B)>

B-1: triphenylsulfonium nonafluoro-n-butanesulfonate

### <Acid Diffusion Controller (D)>

D-1: 2-phenylbenzimidazole

### [3] Evaluation of Negative-Tone Radiation-Sensitive Composition

The following properties (1) to (4) of the compositions prepared in the examples and comparative examples were evaluated according to the following methods. The results of the evaluation are shown in Table 2.

### (1) Sensitivity

### (1-1) KrF Exposure

An 8-inch silicon wafer on which an underlayer antireflection film with a thickness of 60 nm (“DUV42-6” manufactured by Nissan Chemical Industries, Ltd.) had been formed was used as a substrate. “CLEAN TRACK ACT8” (manufactured by Tokyo Electron Ltd.) was used for preparing the underlayer antireflection film. A film with a thickness of 600 nm was formed on the substrate by spin coating the radiation-sensitive composition shown in Table 1 using CLEAN TRACK ACT8 and baking (PB) the composition under the conditions shown in Table 2. The film was exposed to radiation through a mask pattern using a KrF excimer laser exposure apparatus (“NSR S203B” manufactured by Nikon Corp.) under the conditions of NA=0.68 and σ=0.75−½ annular illumination. After PEB under the conditions shown in Table 2, a resist film was developed in a 2.38 mass % tetramethylammonium hydroxide aqueous solution at 23° C. for 60 seconds, washed with water, and dried to form a negative-tone pattern. An optimum exposure amount at which a line-and-space (1L1S) pattern with a line width of 250 nm was formed was taken as sensitivity (mJ/cm²). A scanning electron microscope (“S-9380” manufactured by Hitachi High-Technologies Corporation) was used for measuring the line width.

### (1-2) ArF Exposure (Line-and-Space Pattern (L/S))

An 8-inch silicon wafer on which an underlayer antireflection film with a thickness of 77 nm (“ARC29A” manufactured by Bruwer Science) had been formed was used as a substrate. “CLEAN TRACK ACT8” (manufactured by Tokyo Electron Ltd.) was used for preparing the underlayer antireflection film. A film with a thickness of 400 nm was formed on the substrate by spin coating the radiation-sensitive composition shown in Table 1 using CLEAN TRACK ACT8 and baking (PB) the composition under the conditions shown in Table 2. The film was exposed to radiation through a mask pattern using an ArF excimer laser exposure apparatus (“NSR S306C” manufactured by Nikon Corp.) under the conditions of NA=0.78 and σ=0.85−½ annular illumination. After PEB under the conditions shown in Table 2, a resist film was developed in a 2.38 mass % tetramethylammonium hydroxide aqueous solution at 23° C. for 60 seconds, washed with water, and dried to form a negative-tone pattern. An optimum exposure amount at which a line-and-space (1L1S) pattern with a line width of 250 nm was formed was taken as sensitivity (mJ/cm²). A scanning electron microscope (“S-9380” manufactured by Hitachi High-Technologies Corporation) was used for measuring the line width.

### (1-3) ArF Exposure (Contact Hole Pattern (H/S))

An 8-inch silicon wafer on which an underlayer antireflection film with a thickness of 77 nm (“ARC29A” manufactured by Bruwer Science) had been formed was used as a substrate. “CLEAN TRACK ACT8” (manufactured by Tokyo Electron Ltd.) was used for preparing the underlayer antireflection film. A film with a thickness of 400 nm was formed on the substrate by spin coating the radiation-sensitive composition shown in Table 1 using CLEAN TRACK ACT8 and baking (PB) the composition under the conditions shown in Table 2. The film was exposed to radiation through a mask pattern using an ArF excimer laser exposure apparatus (“NSR S306C” manufactured by Nikon Corp.) under the conditions of NA=0.78 and σ=0.85−½ annular illumination. After PEB under the conditions shown in Table 2, a resist film was developed in a 2.38 mass % tetramethylammonium hydroxide aqueous solution at 23° C. for 60 seconds, washed with water, and dried to form a negative-tone pattern. An optimum exposure amount at which a contact hole (1H1S) pattern with a diameter of 250 nm was formed was taken as sensitivity (mJ/cm²). A scanning electron microscope (“S-9380” manufactured by Hitachi High-Technologies Corporation) was used for measuring the line width.

### (1-4) Electron Beam (EB) Exposure

An 8-inch silicon wafer on which an underlayer antireflection film with a thickness of 77 nm (“ARC29A” manufactured by Brewer Science) had been formed was used as a substrate. “CLEAN TRACK ACT8” (manufactured by Tokyo Electron Ltd.) was used for preparing the underlayer antireflection film. A film with a thickness of 60 nm was formed on the substrate by spin coating the radiation-sensitive composition shown in Table 1 using CLEAN TRACK ACT8 and baking (PB) the composition under the conditions shown in Table 2. The resist film was exposed to electron beams using a simplified electron beam drawing apparatus (“HL800D” manufactured by Hitachi, Ltd., output: 50 KeV, current density: 5.0 A/cm²). After PEB under the conditions shown in Table 2, a resist film was developed in a 2.38 mass % tetramethylammonium hydroxide aqueous solution at 23° C. for 60 seconds, washed with water, and dried to form a negative-tone pattern. An optimum exposure amount at which a line-and-space (1L1S) pattern with a line width of 150 nm was formed was taken as sensitivity (μC/cm²). A scanning electron microscope (“S-9380” manufactured by Hitachi High-Technologies Corporation) was used for measuring the line width.

### (2) Cross-Sectional Shape of Pattern

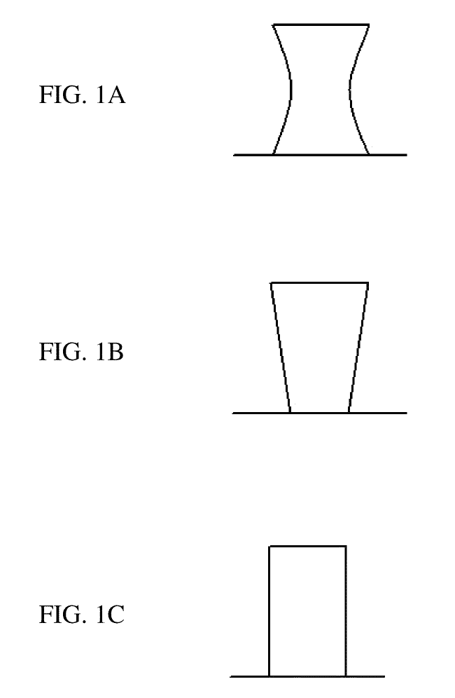

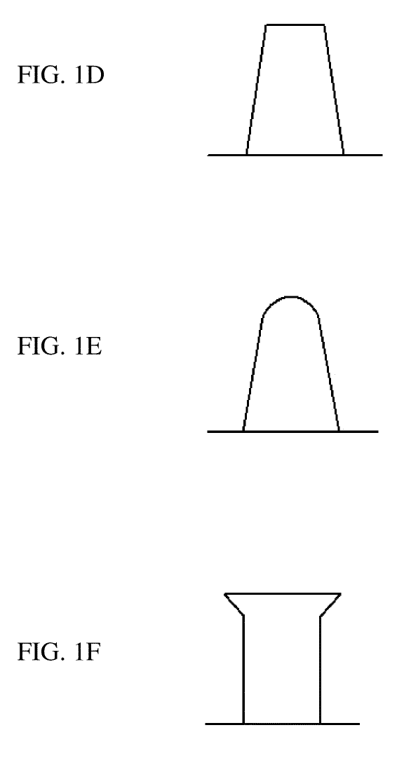

The cross-sectional shape of the line-and-space pattern (1L1S) with a line width of 250 nm formed in the same manner as in (1) above was observed. The cross-sectional shape shown in (b), (c), or (d) in FIG. 1 was evaluated as “Good” and the cross-sectional shape shown in (a), (e), or (f) was evaluated as “Bad”. “S-4800” manufactured by Hitachi High-Technologies Corporation was used for observing the cross-sectional shape.

### (3) Marginal Resolution

1L1S patterns of various line widths were observed at the sensitivity of the line-and-space pattern (1L1S) with a line width of 250 nm measured in (1) above. The minimum width pattern resolved at this time was taken as the marginal resolution. A scanning electron microscope (“S-9380” manufactured by Hitachi High-Technologies Corporation) was used for measuring the line width.

### (4) Exposure Margin

1L1S patterns at various exposure amounts were observed at the sensitivity of the line-and-space pattern (1L1S) with a line width of 250 nm measured in (1) above to calculate exposure margin according to the following formula.

A scanning electron microscope (“S-9380” manufactured by Hitachi High-Technologies Corporation) was used for measuring the line width. The evaluation was omitted for examples in which electron beams were used for exposure in (1) above.

Exposure margin(%)=[(E1−E2)/Eop]×100

E1: Exposure amount (mJ) when the line width is 275 nm
E2: Exposure amount (mJ) when the line width is 225 nm
Eop: Optimum exposure amount (mJ) when the line width is 250 nm

### (5) Depth of Focus

The 1L1S patterns at various focuses were observed at the sensitivity of the line-and-space pattern (1L1S) with a line width of 250 nm measured in (1) above to calculate the depth of focus according to the following formula.

A scanning electron microscope (“S-9380” manufactured by Hitachi High-Technologies Corporation) was used for measuring the line width. The evaluation was omitted for examples in which electron beams were used for exposure in (1) above.

Depth of focus(μm)=|F1−F2|(i.e., the absolute value of the difference between F1 and F2)

F1: Focus (μm) when the line width is 275 nm
F2: Focus (μm) when the line width is 225 nm

### (6) Measurement of Relative Dielectric Constant

As a substrate, an 8-inch N-type silicon wafer having a resistivity of 0.1 ohm·cm or less was used. A film with a thickness of 600 nm was formed on the substrate by spin coating the radiation-sensitive compositions shown in Tables 1 and 2 using CLEAN TRACK ACT8 and baking (PB) the composition under the conditions shown in Table 2. The entire surface of the wafer was exposed without using a mask to irradiate the film with a KrF excimer laser using a liquid immersion lithographic apparatus, “NSR S203B” (manufactured by Nikon Corp.) under the conditions of NA=0.68 and σ=0.75. After PEB under the conditions shown in Table 2, the resist pattern was developed in a 2.38 mass % tetramethylammonium hydroxide aqueous solution at 23° C. for 60 seconds, washed with water, and dried, followed by heating at 420° C. for 30 minutes in a nitrogen atmosphere to obtain a cured film.

An aluminum electrode pattern was formed on the resulting film by vapor deposition to obtain a sample for measuring a relative dielectric constant. The relative dielectric constant of the sample was measured at room temperature (24° C.) and 200° C. by a CV method at a frequency of 100 kHz using an electrode “HP16451B” and a precision LCR meter “HP4284A”, both manufactured by Agilent Technologies.

TABLE 2

| | | | | | | | | | | Depth | |
|---|---|---|---|---|---|---|---|---|---|---|---|
| | | | | | | | | Marginal | Exposure | of | Relative |
| | Exposure | | PB | PEB | Sensitivity | | Pattern | resolution | margin | focus | dielectric |
| Examples | light | Pattern | (° C./60 sec) | (° C./60 sec) | (mJ/cm²) | | shape | (nm) | (%) | (μm) | constant |
| Comparative | KrF | L/S | 90 | 85 | 45 | | Bad | 400 | — | — | 3 |
| Examples 1 | | | | | | | | | | | |
| Examples 1 | KrF | L/S | 90 | 85 | 40 | | Good | 220 | 20 | 0.8 | 2.6 |
| Examples 2-1 | KrF | L/S | 90 | 85 | 34 | | Good | 180 | 30 | 1.2 | 2.6 |
| Examples 2-2 | ArF | L/S | 90 | 85 | 12 | | Good | 140 | 20 | 0.5 | 2.6 |
| Examples 2-3 | ArF | H/S | 90 | 85 | 22 | | Good | 140 | 20 | 0.2 | 2.6 |
| Examples 2-4 | EB | L/S | 90 | 85 | 27 | μm/cm² | Good | 90 | — | — | 2.6 |
| Examples 3-1 | KrF | L/S | 90 | 85 | 34 | | Good | 180 | 30 | 1.2 | 2.6 |
| Examples 3-2 | KrF | L/S | 90 | 85 | 12 | | Good | 140 | 20 | 0.5 | 2.6 |
| Examples 3-3 | EB | L/S | 90 | 85 | 27 | μm/cm² | Good | 90 | — | — | 2.6 |
| Examples 4 | KrF | L/S | 90 | 85 | 33 | | Good | 220 | 21 | 0.8 | 2.8 |
| Examples 5 | KrF | L/S | 90 | 85 | 38 | | Good | 220 | 18 | 0.5 | 2.8 |
| Examples 6-1 | KrF | L/S | 90 | 85 | 33 | | Good | 190 | 28 | 1 | 2.7 |
| Examples 6-2 | ArF | L/S | 90 | 85 | 11 | | Good | 160 | 18 | 0.4 | 2.7 |
| Examples 7 | KrF | L/S | 90 | 85 | 32 | | Good | 210 | 18 | 0.4 | 2.8 |
| Examples 8-1 | KrF | L/S | 90 | 85 | 32 | | Good | 350 | — | — | 2.8 |
| Examples 8-2 | ArF | L/S | 90 | 85 | 32 | | Good | 200 | 5 | 0.3 | 2.7 |
| Examples 8-2 | ArF | H/S | 90 | 85 | 32 | | Good | 130 | 20 | 0.3 | 2.7 |
| Comparative | KrF | L/S | 90 | 85 | Not resolved. | | | | | | 2.8 |
| Examples 2-1 | | | | | | | | | | | |
| Comparative | ArF | L/S | 90 | 85 | Not resolved. | | | | | | 2.7 |
| Examples 2-2 | | | | | | | | | | | |
| Comparative | ArF | H/S | 90 | 85 | Not resolved. | | | | | | 2.7 |
| Examples 2-3 | | | | | | | | | | | |
| Comparative | KrF | L/S | 90 | 85 | 33 | | Good | 350 | | | 2.7 |
| Examples 3 | | | | | | | | | | | |
| Examples 9 | KrF | L/S | 90 | 85 | 34 | | Good | 200 | 18 | 0.5 | 2.7 |
| Examples 10 | KrF | L/S | 90 | 85 | 36 | | Good | 210 | 24 | 0.8 | 2.7 |
| Examples 11-1 | KrF | L/S | 90 | 85 | 36 | | Good | 200 | 24 | 0.8 | 2.7 |
| Examples 11-2 | ArF | L/S | 90 | 85 | 15 | | Good | 150 | 15 | 0.4 | 2.7 |
| Examples 12 | KrF | L/S | 90 | 85 | 34 | | Good | 190 | 28 | 0.8 | 2.6 |
| Examples 13 | KrF | L/S | 90 | 85 | 36 | | Good | 240 | 20 | 0.4 | 2.8 |
| Examples 14-1 | KrF | L/S | 90 | 85 | 35 | | Good | 180 | 26 | 1 | 2.6 |
| Examples 14-2 | ArF | L/S | 90 | 85 | 13 | | Good | 150 | 16 | 0.4 | 2.6 |
| Examples 15 | KrF | L/S | 90 | 85 | 37 | | Good | 180 | 24 | 0.8 | 2.6 |
| Examples 16 | KrF | L/S | 90 | 85 | 34 | | Good | 190 | 28 | 1 | 2.7 |
| Examples 17 | KrF | L/S | 90 | 85 | 35 | | Good | 200 | 25 | 0.8 | 2.7 |
| Examples 18-1 | KrF | L/S | 90 | 85 | 34 | | Good | 180 | 30 | 1.2 | 2.6 |
| Examples 18-2 | ArF | L/S | 90 | 85 | 12 | | Good | 140 | 20 | 0.5 | 2.6 |
| Examples 18-3 | EB | L/S | 90 | 85 | 27 | μm/cm² | Good | 90 | — | — | 2.6 |

| | | | | | | |
|---|---|---|---|---|---|---|
| Comparative | KrF | L/S | 110 | 110 | Not resolved. | 2.7 |
| Examples 4 | | | | | | |

### [4] Formation of Cured Pattern Having Dual Damascene Structure

### Example 3-4

An 8-inch silicon wafer on which an underlayer antireflection film with a thickness of 60 nm (“DUV42-6” manufactured by Nissan Chemical Industries, Ltd.) had been formed was used as a substrate. “CLEAN TRACK ACT8” (manufactured by Tokyo Electron Ltd.) was used for preparing the underlayer antireflection film. A film with a thickness of 500 nm was formed on the substrate by spin coating the radiation-sensitive composition of Example 3 using CLEAN TRACK ACT8 and baking (PB) at 90° C. for 60 seconds. The film was exposed to a KrF excimer laser at an exposure amount of 28 mJ/cm² through a mask having a hole pattern using a KrF excimer laser exposure apparatus (“NSR S203B” manufactured by Nikon Corp.) under the conditions of NA=0.68 and σ=0.75−½ annular illumination. After baking (PEB) at 85° C. for 60 seconds, the resist pattern was developed in a 2.38 mass % tetramethylammonium hydroxide aqueous solution at 23° C. for 60 seconds, washed with water, and dried, followed by heating at 250° C. for 2 minutes to form a negative-tone resist pattern substrate having a negative-tone hole pattern with a hole-and-space (1H2S) pattern having a hole diameter of 200 nm

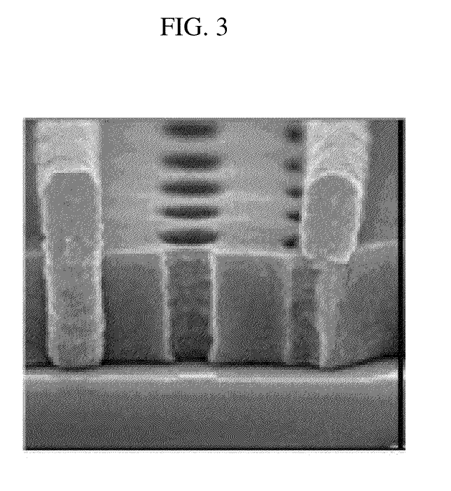

A film with a thickness of 500 nm was formed on the negative-tone hole pattern substrate by spin coating the radiation-sensitive composition of Example 3 using CLEAN TRACK ACT8 and baking (PB) at 90° C. for 60 seconds. The film was exposed to a KrF excimer laser at an exposure amount of 32 mJ/cm² through a mask having a line pattern using a KrF excimer laser exposure apparatus (“NSR S203B” manufactured by Nikon Corp.) under the conditions of NA=0.68 and σ=0.75−½ annular illumination. After baking (PEB) at 85° C. for 60 seconds, the resist pattern was developed in a 2.38 mass % tetramethylammonium hydroxide aqueous solution at 23° C. for 60 seconds, washed with water, and dried to form a negative-tone line pattern with a line-and-space (1L3S) pattern having a line width of 240 nm on a negative-tone hole pattern substrate, followed by heating at 420° C. for 30 minutes in a nitrogen atmosphere to obtain a cured pattern having a dual damascene structure (FIG. 3).

As clearly shown in Table 2, the results of the Examples confirmed that the negative-tone radiation-sensitive composition according to the embodiment of the present invention possesses sufficient pattern forming capability. It was further confirmed that the cured film (cured pattern) formed by applying and curing the negative-tone radiation-sensitive composition according to the embodiment of the present invention has a relative dielectric constant of 2.8 or less.

Since the negative-tone radiation-sensitive composition according to the embodiment of the present invention is sensitive to radiation, can be patterned, and has a low relative dielectric constant when cured, the composition is suitable as an interlayer dielectric of a semiconductor device or the like.

Moreover, since a negative-tone pattern having a dual damascene structure can be easily formed using the negative-tone radiation-sensitive composition, the negative-tone radiation-sensitive composition is suitable as an interlayer dielectric of a semiconductor device or the like.

### Example Group II

### [1] Preparation of Polysiloxane (A)

Polysiloxanes (A-22) to (A-25) were synthesized as follows using the following organosilicon compounds.

### <Compound (I)>

(a1-1) vinyltrimethoxysilane
(a1-2) allyltrimethoxysilane
(a1-3) methyltrimethoxysilane

### <Compound (2)>

(a2-1) tetramethoxysilane

### <Compound (3)>

(a3-1) bis(triethoxysilyl)ethane

### (1) Synthesis of Polysiloxane (A-22)

A nitrogen-replaced flask was charged with 1 part of a 20% maleic acid aqueous solution and 69 parts of ultrapure water, and the mixture was heated to 65° C. After dropwise addition of a mixed solution of 36 parts of vinyltrimethoxysilane (a1-1), 55 parts of methyltrimethoxysilane (a1-3), 25 parts of tetramethoxysilane (a2-1), and 14 parts of propylene glycol monoethyl ether to the reaction vessel over one hour, the mixture was stirred at 65° C. for two hours. The reaction solution was allowed to cool to room temperature and concentrated under reduced pressure to a solid concentration of 30% to obtain polysiloxane (A-22). The ratio of the monomers forming each unit [(a1-1):(a1-3):(a2-1)] in the polysiloxane (A-22) was [30:50:20] (mol %), and the Mw was 3500.

### (2) Synthesis of Polysiloxanes (A-23) to (A-26)

Polysiloxanes (A-23) to (A-26) were synthesized in the same manner as in the synthesis of the polysiloxane (A-22) described above, except for using ultrapure water in the amount shown in the following Table 3, organosilicon compounds of the type and amount shown in the following Table 3, and the reaction temperature shown in the following Table 3.

Table 3 also shows the Mw of each polysiloxane. The content of each monomer forming the polysiloxanes (in terms of a theoretical value (mol %) determined from the used amount of each monomer) was as follows.

### <Polysiloxane (A-23)>

(a1-2):(a1-3):(a2-1)]=[30:50:20]

### <Polysiloxane (A-24)>

(a1-1):(a1-3):(a3-1)]=[30:40:30]

### <Polysiloxane (A-25)>

(a1-1):(a1-3)=[20:80]

### <Polysiloxane (A-26)>

(a1-3):(a2-1)]=[20:80]

TABLE 3

| | | Polysiloxane | | | | |
|---|---|---|---|---|---|---|
| | | (A-22) | (A-23) | (A-24) | (A-25) | (A-26) |
| (a1-1) | Vinyltrimethoxysilane (parts by mass) | 36 | — | 32 | 24 | — |
| (a1-2) | Allyltrimethoxysilane (parts by mass) | — | 39 | — | — | — |
| (a1-3) | Methyltrimethoxysilane (parts by mass) | 55 | 55 | 39 | 88 | 22 |
| (a2-1) | Tetramethoxysilane (parts by mass) | 25 | 25 | — | — | 100 |
| (a3-1) | Bis(triethoxysilyl)ethane (parts by mass) | — | — | 76 | — | — |

| | | | | | |
|---|---|---|---|---|---|
| Ultrapure water (parts by mass) | 69 | 69 | 74 | 65 | 83 |
| Reaction temperature (° C.) | 65 | 65 | 75 | 65 | 40 |
| Weight average molecular weight | 3500 | 3200 | 4000 | 2100 | 13000 |

### [2] Preparation of Negative-Tone Radiation-Sensitive Resin Composition

### Example 18

100 parts of polysiloxane (A) [above polysiloxane (A-22)], two parts of an acid generator (B) [(B-2): triphenylsulfonium 2-(bicyclo[2.2.1]hept-2′-yl)-1,1,2,2-tetrafluoroethanesulfonate], a solvent [propylene glycol monoethyl ether], and 0.02 parts of an acid diffusion controller (D)

[(D-1):2-phenylbenzimidazole] were mixed to make a solid content of 17%, thereby obtaining a negative-tone radiation-sensitive resin composition of Example 18.

### Examples 19 to 21 and Comparative Example 5

Negative-tone radiation-sensitive resin compositions of Examples 19 to 21 and Comparative Example 5 (solid content: 17%) were prepared in the same manner as in Example 18, except for using the components shown in Table 4 in amounts shown in Table 4.

TABLE 4

| | | Photoacid | Acid diffusion | |
|---|---|---|---|---|
| | | Generator (B) | controller (D) | Solid |
| | Polysiloxane | (Type/parts | (Type/parts | content |
| | (A) | by mass) | by mass) | (mass %) |
| Example 18 | A-22/100 | B-2/2 | D-1/0.02 | 17 |
| Example 19 | A-23/100 | B-1/2 | D-2/0.02 | 17 |
| Example 20 | A-24/100 | B-1/2 | D-1/0.02 | 17 |
| Example 21 | A-25/100 | B-1/2 | D-1/0.02 | 17 |
| Comparative | A-26/100 | B-1/2 | D-1/0.02 | 17 |
| Example 5 | | | | |

The components shown in Table 4 are as follows.

### <Acid Generator (B)>

(B-1): triphenylsulfonium nonafluoro-n-butanesulfonate
(B-2): triphenylsulfonium 2-bicyclo[2.2.1]hept-2-yl-1,1,2,2-tetrafluoroethanesulfonate

### <Acid Diffusion Controller (D)>

(D-1): 2-phenylbenzimidazole
(D-2): N-t-butoxycarbonyl-2-phenylbenzimidazole

### [3] Evaluation of Negative-Tone Radiation-Sensitive Composition

The following properties (1) to (4) of the compositions prepared in the Examples 1 to 4 and Comparative Examples 1 and 2 were evaluated according to the following methods. The results are shown in Table 5.

### (1) Marginal Resolution Measurement

### (Krf Exposure)

An eight-inch silicon wafer on which a lower layer antireflection film with a thickness of 60 nm (“DUV42-6” manufactured by Nissan Chemical Industries, Ltd.) had been formed was used as a substrate. A semiconductor manufacturing equipment, “CLEAN TRACK ACTS” (manufactured by Tokyo Electron Ltd.) was used for preparing the lower layer antireflection film.

A film with a thickness of 500 nm was formed on the above-mentioned substrate by spin coating the negative-tone radiation sensitive resin compositions of Examples 1 to 4 and Comparative Examples 1 and 2 and baking (PB) at 85° C. for 60 seconds using this semiconductor manufacturing equipment. The film was exposed to exposure light through a photomask having a line-and-space pattern with a covering rate of 100% using a KrF excimer laser exposure apparatus (“NSR S203B” manufactured by Nikon Corp.) under the conditions of NA=0.68 and σ=0.75, and ½ annular illumination. After PEB at 85° C. for 60 seconds, the film was developed in a 2.38 mass % tetramethylammonium hydroxide aqueous solution at 23° C. for 60 seconds, washed with water, and dried to form a negative-tone pattern, followed by curing by heating at 420° C. for 180 minutes in a nitrogen atmosphere to obtain a cured pattern.

The minimum line width cured pattern resolved at this time was taken as the marginal resolution. A scanning electron microscope (“S-9380” manufactured by Hitachi High-Technologies Corporation) was used for measuring the line width.

### (2) Pattern Shape

The cross-section form of the line-and-space pattern (1L1S) with a line width of 300 nm of the cured pattern formed in the same manner as in (1) above was observed. The cross-section forms shown in FIGS. 1B, 1C, and 1D were evaluated as “Good” and the cross-section forms shown in FIGS. 1A, 1E, and 1F were evaluated as “Bad”.

A scanning electron microscope “S-4800” manufactured by Hitachi High-Technologies Corporation was used for observing the cross-section form.

### (3) Measurement of Relative Dielectric Constant

As a substrate, an eight-inch N-type silicon wafer having a resistivity of 0.1 Ω·cm or less was used. A film with a thickness of 500 nm was formed on the substrate by spin coating the negative-tone radiation sensitive resin compositions of Examples 1 to 4 and Comparative Examples 1 and 2 and baking (PB) at 85° C. for 60 seconds using an semiconductor manufacturing equipment “CLEAN TRACK ACTS” (manufactured by Tokyo Electron, Ltd.). Without using a mask, the entire surface of the wafer was exposed to radiation by a KrF excimer laser liquid immersion lithography apparatus (“NSR S203B” manufactured by Nikon Corp.) under the conditions of NA=0.68 and σ=0.75. After PEB at 85° C. for 60 seconds, the development was carried out in a 2.38 mass % tetramethylammonium hydroxide aqueous solution at 23° C. for 60 seconds, washed with water, and dried to form a whole surface film without a negative-tone pattern.

A cured whole surface film was obtained by treating this film using a treating method (i) or (ii) as shown in Table 5.

An aluminum electrode pattern was formed on the resulting film by vapor deposition to obtain a sample for measuring a relative dielectric constant. The relative dielectric constant of the cured film at 200° C. was measured by a CV method at a frequency of 100 kHz using an electrode “HP16451B” and a precision LCR meter “HP4284A”, both manufactured by Agilent Technologies.

### (i) Heat Treatment

The whole surface film was heated at 420° C. for one hour under vacuum.

### (ii) Ultraviolet Irradiation

The whole surface film was exposed to ultraviolet rays for 8 minutes in a chamber with an oxygen partial pressure of 0.01 kPa while heating the coated film at 400° C. on a hot plate. White ultraviolet rays containing a wavelength of 250 nm or less was used. Since the white ultraviolet rays was used, the degree of luminance could not be measured by an effective method.

### (4) Measurement of Modulus of Elasticity (Young's Modulus of Elasticity)

The modulus of elasticity of the cured film obtained by the same method as in (3) above was measured by a continuous rigidity measuring method by attaching a Bercovitch indenter to a supermicro hardness meter (“Nanoindentator XP” manufactured by MTS System Corp.).

TABLE 5

| | Exposure | Marginal | Pattern | | Relative dielectric | Modulus of |
|---|---|---|---|---|---|---|
| | light | resolution (nm) | shape | Curing treatment | constant | elasticity (Gpa) |
| Example 18 | KrF | 240 | Good | (ii) Ultraviolet irradiation | 2.7 | 15.2 |
| Example 19 | KrF | 240 | Good | (ii) Ultraviolet irradiation | 2.7 | 14.7 |
| Example 20 | KrF | 280 | Good | (i) Heat treatment | 2.8 | 11.2 |
| | | | | (ii) Ultraviolet irradiation | 2.5 | 19.3 |
| Example 21 | KrF | 280 | Good | (ii) Ultraviolet irradiation | 2.7 | 10.1 |
| Comparative | KrF | No pattern was | — | (i) Heat treatment | 3 | 9.1 |
| Example 5 | | formed. | | | | |

### [4] Evaluation of Examples

Table 5 shows that cured patterns with a low relative dielectric constant and high modulus of elasticity can be formed by using the negative-tone radiation-sensitive resin composition of Examples 1 to 4.

The composition according to the embodiment of the present invention is sensitive to radiation, can be patterned, and can easily produce a cured pattern with a low relative dielectric constant. Therefore, the composition is useful as a microfabrication material for semiconductor devices such as an LSI, system LSI, DRAM, SDRAM, RDRAM, and D-RDRAM. The composition is an excellent material for an interlayer dielectric, and is useful for producing semiconductor devices using a copper damascene process. The pattern forming method according to the embodiment of the present invention can be suitably used in a process requiring an interlayer dielectric with a low relative dielectric constant and can significantly improve the efficiency of a process using an interlayer dielectric.

Obviously, numerous modifications and variations of the present invention are possible in light of the above teachings. It is therefore to be understood that within the scope of the appended claims, the invention may be practiced otherwise than as specifically described herein.

What is claimed is:

1. A negative-tone radiation-sensitive composition comprising (A) a polymer, (B) a photoacid generator, and (C) a solvent,
the polymer (A) being obtained by hydrolysis and condensation of at least one hydrolyzable silane compound selected from (1) a hydrolyzable silane compound shown by the following formula (1), (2) a hydrolyzable silane compound shown by the following formula (2), and (3) a hydrolyzable silane compound shown by the following formula (3),
RₐSi(OR¹)₄₋ₐ (1)
wherein R represents a fluorine atom, a linear or branched alkyl group having 1 to 5 carbon atoms, an alkenyl group having 2 to 6 carbon atoms, or an alkylcarbonyloxy group, R¹ represents a monovalent organic group, and a represents an integer from 1 to 3,
Si(OR²)₄ (2)
wherein R² represents a monovalent organic group,
R³ₓ(R⁴O)₃₋ₓSi—(R⁷)_{z}—Si(OR⁵)_{3-y}R⁶_{y} (3)
wherein R³ and R⁶ individually represent a fluorine atom, an alkylcarbonyloxy group, or a linear or branched alkyl group having 1 to 5 carbon atoms, R⁴ and R⁵ individually represent a monovalent organic group, x and y individually represent a number from 0 to 2, and R⁷ represents an oxygen atom, a phenylene group, or a group —(CH₂)ₘ— (wherein m represents an integer from 1 to 6), and z represents 0 or 1,
the content of units derived from the compound (1) being 50 to 100 mol % of the total units forming the polymer (A).

2. The composition according to claim 1, wherein the compound (1) contains a compound having a methyl group for R in the formula (1), and the polymer (A) has a polystyrene-reduced weight average molecular weight determined by gel permeation chromatography of 4000 to 200,000.

3. The composition according to claim 1, wherein the compound (a1) contains a compound having an alkenyl group having 2 to 6 carbon atoms represented by the following formula (i) for R in the formula (1),
CH₂═CH—(CH₂)ₙ—* (i)
wherein n is an integer from 0 to 4 and * indicates a bonding hand.

4. The composition according to claim 1, wherein the content of the photoacid generator (B) is 0.1 to 30 parts by mass based on 100 parts by mass of the polymer (A).

5. The composition according to claim 1, further comprising (D) an acid diffusion controller.

6. The composition according to claim 1, the composition being used for forming a low-dielectric-constant film which can be patterned by applying radiation.

7. A method for forming a cured pattern comprising (I-1) applying the composition according to claim 1 to a substrate to form a film, (I-2) baking the resulting film, (I-3) exposing the baked film, (I-4) developing the exposed film using a developer to form a negative-tone pattern, and (I-5) applying at least one of high energy rays and heat to the resulting negative-tone pattern to form a cured pattern.

8. A cured pattern obtained by the method according to claim 7.

9. The cured pattern according to claim 8, having a relative dielectric constant of 1.5 to 3.

10. A method for forming a cured pattern comprising (II-1) applying the composition according to claim 1 to a substrate, followed by exposure and development to form a negative-tone hole pattern substrate having a negative-tone hole pattern, (II-2) applying the composition according to claim 1 to the resulting negative-tone hole pattern substrate, followed by exposure and development to form a negative-tone trench pattern on the negative-tone hole pattern substrate, thereby forming a negative-tone dual damascene pattern substrate, and (II-3) applying at least one of high energy rays and heat to the resulting negative-tone dual damascene pattern substrate to form a cured pattern having a dual damascene structure.

11. A cured pattern obtained by the method according to claim 10.

12. The cured pattern according to claim 11, the cured pattern having a relative dielectric constant of 1.5 to 3.
